(19) United States
(12) Patent Application Publication
(10) Pub. No.: US 2026/0182432 A1
(43) Pub. Date: Jun. 25, 2026

(54) SEMICONDUCTOR CHIP INCLUDING TOP PAD AND SIDE PAD AND SEMICONDUCTOR PACKAGE INCLUDING THE SAME

(71) Applicant: Samsung Electronics Co., Ltd., Suwon-si (KR)

(72) Inventors: Hyun Cheol AHN, Suwon-si (KR); Sungmoon JI, Suwon-si (KR); Chan-Sik KWON, Suwon-si (KR); Jee-Min PARK, Suwon-si (KR); Ji-Yeon HAN, Suwon-si (KR)

(73) Assignee: Samsung Electronics Co., Ltd., Suwon-si (KR)

(21) Appl. No.: 19/407,432

(22) Filed: Dec. 3, 2025

(30) Foreign Application Priority Data
Dec. 19, 2024 (KR) 10-2024-0191247

(51) Int. Cl. H10W 72/00

(52) U.S. Cl. CPC H10W 72/812; H10W 72/944; H10W 72/983; H10W 90/24

(57) ABSTRACT

A semiconductor chip and a semiconductor package including the semiconductor chip, the semiconductor chip including a top pad exposed through an upper surface of the semiconductor chip, and a side pad electrically connected to the top pad and exposed through a sidewall of the semiconductor chip.

### CROSS-REFERENCE TO RELATED APPLICATION(S)

This application claims priority to and the benefit of Korean Patent Application No. 10-2024-0191247, filed on Dec. 19, 2024, in the Korean Intellectual Property Office, the disclosure of which is incorporated by reference herein in its entirety.

### BACKGROUND

Some example embodiments of the present disclosure described herein relate to semiconductor chips and semiconductor packages including the semiconductor chips.

The demand for high-capacity semiconductor packages is continuously increasing, driven by the need for higher-capacity memory devices in information technology (IT) devices. To meet this demand, semiconductor package manufacturing technology has adopted a method of stacking multiple semiconductor chips during the assembly process in order to achieve higher capacities. The stacked semiconductor chips are electrically connected to each other by bonding wires. However, the method of using the bonding wires has disadvantage of long wire lengths and small diameters, which result in longer transmission times for electrical signals, higher impedance that reduces signal reliability, and difficulty in producing a thin package design.

### SUMMARY

Some example embodiments of the present disclosure provide a semiconductor chip capable of providing improved operational reliability and/or a high-capacity package, and a semiconductor package including the semiconductor chip.

Some example embodiments of the inventive concepts provide semiconductor package that includes a first semiconductor chip; a second semiconductor chip stacked on the first semiconductor chip; and a printed pattern electrically connecting the first semiconductor chip and the second semiconductor chip. The first semiconductor chip includes a first top pad exposed through an upper surface of the first semiconductor chip, and a first side pad electrically connected to the first top pad, the first side pad being exposed through a sidewall of the first semiconductor chip. The second semiconductor chip includes a second top pad exposed through an upper surface of the second semiconductor chip, and a second side pad electrically connected to the second top pad, the second side pad being exposed through a sidewall of the second semiconductor chip. The printed pattern electrically connects the first top pad and the second side pad.

Some example embodiments of the inventive concepts further provide semiconductor package that includes a substrate including a plurality of substrate pads, the substrate extending in a first direction; and a plurality of semiconductor chips extending in a second direction perpendicular to the first direction, the plurality of semiconductor chips being on the substrate next to each other along the first direction. Each semiconductor chip from among of the plurality of semiconductor chips includes a top pad exposed through an upper surface of the semiconductor chip, and a pad conductive pattern exposed through a sidewall of the semiconductor chip, the pad conductive pattern being electrically connected to the top pad. The pad conductive pattern of at least one semiconductor chip from among the plurality of semiconductor chips is electrically connected to at least one substrate pad from among the plurality of substrate pads.

Some example embodiments of the inventive concepts still further provide a semiconductor chip that includes an upper surface; a sidewall; a top pad exposed through the upper surface; and a side pad electrically connected to the top pad, the side pad being exposed through the sidewall.

According to some example embodiments, the semiconductor chip and the semiconductor package including the semiconductor chip provide improved operational reliability and/or a high-capacity package.

### BRIEF DESCRIPTION OF THE FIGURES

The above and other objects and features of the present disclosure will become apparent in view of the following detailed description of some example embodiments thereof with reference to the accompanying drawings.

FIG. 1A is a perspective view illustrating a semiconductor chip according to some example embodiments of the present disclosure;

FIG. 1B is a cross-sectional view taken along a line A1-A1′ of FIG. 1A;

FIG. 2A is a perspective view illustrating a semiconductor chip according to some example embodiments of the present disclosure;

FIG. 2B is a cross-sectional view taken along a line A2-A2′ of FIG. 2A;

FIG. 3A is a perspective view illustrating a semiconductor chip according to some example embodiments of the present disclosure;

FIG. 3B is a cross-sectional view taken along a line B1-B1′ of FIG. 3A;

FIG. 4A is a perspective view illustrating a semiconductor chip according to some example embodiments of the present disclosure;

FIG. 4B is a cross-sectional view taken along a line B2-B2′ of FIG. 4A;

FIGS. 5A, 5B and 5C are views illustrating a semiconductor chip according to some example embodiments of the present disclosure;

FIGS. 6A, 6B and 6C are views illustrating a semiconductor chip according to some example embodiments of the present disclosure;

FIGS. 7A, 7B and 7C are views illustrating a semiconductor chip according to some example embodiments of the present disclosure;

FIGS. 8A, 8B and 8C are views illustrating a semiconductor chip formed by vertically stacking multiple chips according to some example embodiments of the present disclosure;

FIG. 9A is a plan view illustrating a semiconductor package according to some example embodiments of the present disclosure;

FIG. 9B is a plan view illustrating a second region of FIG. 9A;

FIG. 9C is a cross-sectional view taken along a line E-E′ of FIG. 9A;

FIG. 10A is a plan view illustrating a semiconductor package according to some example embodiments of the present disclosure;

FIG. 10B is a plan view illustrating a third region of FIG. 10A;

FIG. 10C is a cross-sectional view taken along a line F-F′ of FIG. 10A;

FIG. 10D is a cross-sectional view illustrating a region A of FIG. 10C;

FIG. 10E is a side view illustrating a region A of FIG. 10D;

FIG. 11A is a cross-sectional view illustrating a region A of FIG. 10C according to some example embodiments of the present disclosure;

FIG. 11B is a side view illustrating a region A of FIG. 11A;

FIGS. 12A, 12B, 12C and 12D are views illustrating a semiconductor package according to some example embodiments of the present disclosure; and

FIGS. 13A, 13B and 13C are views illustrating a semiconductor package according to some example embodiments of the present disclosure.

### DETAILED DESCRIPTION

Below, some example embodiments of the present disclosure will be described in detail and clearly to such an extent that one of ordinary skill in the art may easily implement the disclosure.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

### <A Semiconductor Chip Including a Top Pad and a Side Pad>

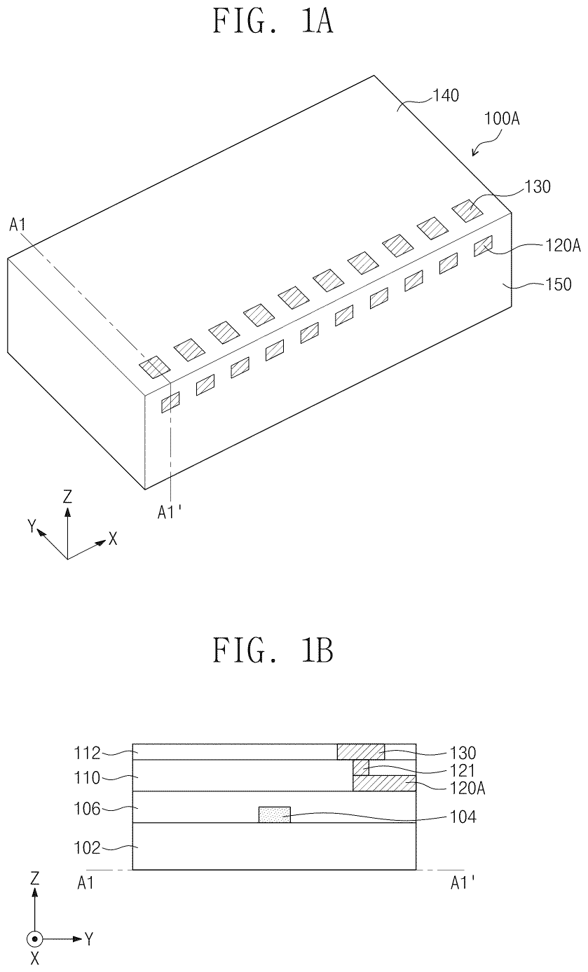

FIG. 1A is a perspective view illustrating a semiconductor chip 100A according to some example embodiments of the present disclosure. FIG. 1B is a cross-sectional view taken along a line A1-A1′ of FIG. 1A.

Referring to FIG. 1A, the semiconductor chip 100A may include an upper surface 140 and at least one sidewall 150.

The upper surface 140 may extend in a first direction (X direction) and a second direction (Y direction) and may be an active surface. A top pad 130 that is a conductive pad may be disposed on the upper surface 140. As an example, the top pad 130 may include aluminum, copper, tungsten, molybdenum, and a conductive material such as titanium nitride, tantalum nitride, or tungsten nitride. However, this is merely an example, and the top pad 130 may include a variety of materials.

The sidewall 150 may extend in the first direction (X direction) and a third direction (Z direction). FIG. 1A shows a structure in which the semiconductor chip 100A includes four sidewalls 150, however, this is merely an example, and according to some example embodiments, the number of sidewalls included in the semiconductor chip 100A may vary.

A conductive pattern 120A may be exposed without being covered by the sidewall 150. For example, the conductive pattern 120A may be exposed to the outside through the sidewall 150. The conductive pattern 120A exposed through the sidewall 150 may serve as a side pad, and thus, the conductive pattern 120A may be referred to as a side pad conductive pattern, a pad conductive pattern, or a side pad. The conductive pattern 120A may include aluminum, copper, tungsten, molybdenum, and a conductive material such as titanium nitride, tantalum nitride, or tungsten nitride. However, this is merely an example, and the conductive pattern 120A may include a variety of materials.

Referring to FIGS. 1A and 1B, a conductive area 104 may be formed on a substrate 102. The conductive area 104 may be one of electrical structures in the semiconductor chip 100A. According to some example embodiments, the substrate 102 may be a semiconductor wafer, and multi-layered patterns may be formed on the semiconductor wafer.

A first interlayer insulating layer 106 may be formed to cover the substrate 102 in which the conductive area 104 is formed. As an example, the first interlayer insulating layer 106 may be formed by depositing a silicon oxide layer.

The conductive pattern 120A may be formed on the first interlayer insulating layer 106. The conductive pattern 120A may extend in the second direction (Y direction), and a portion of the conductive pattern 120A may overlap the top pad 130 when viewed in a horizontal direction. In some example embodiments, the conductive pattern 120A may be exposed to the outside through the sidewall 150. As an example, the conductive pattern 120A may be arranged so that a part of the conductive pattern 120A overlaps a scribe line. In some example embodiments, the conductive pattern 120A may be exposed to the outside through the sidewall 150 by cutting the substrate 102 along the scribe line to separate each semiconductor chip.

The width and thickness of the conductive pattern 120A may be determined in consideration of factors such as a shape of the semiconductor chip 100A, a type of package, and a process of forming the electrical structures inside the semiconductor chip 100A. According to some example embodiments, the conductive pattern 120A may be formed together with the electrical structures inside the semiconductor chip 100A. As an example, the conductive pattern 120A may be formed concurrently with electrical wiring by adding an area for forming the conductive pattern 120A to a mask used for forming the electrical wiring inside the semiconductor chip 100.

A second interlayer insulating layer 110 may be formed to cover the first interlayer insulating layer 106 and the conductive pattern 120A. As an example, the second interlayer insulating layer 110 may be formed by depositing a silicon oxide layer.

The top pad 130 may be formed on the second interlayer insulating layer 110, however, this is merely an example. According to some example embodiments, the top pad 130 may be formed on a protective layer 112. The protective layer 112 may be formed to cover the second interlayer insulating layer 110 and a side surface of the top pad 130. As an example, the protective layer 112 may include a nitride material such as silicon nitride or silicon oxynitride.

A metal contact 121 may be formed to electrically connect the top pad 130 and the conductive pattern 120A. As an example, the metal contact 121 may be formed in the second interlayer insulating layer 110 and may be arranged to connect the top pad 130 and the conductive pattern 120A. As an example, the metal contact 121 may be a through-hole via (THV). According to some example embodiments, the metal contact 121 may be formed of a conductive material such as a metal, a metal compound, or doped polysilicon.

As described with reference to FIGS. 1A and 1B, the semiconductor chip 100A according to the present disclosure may include the top pad 130 and the conductive pattern 120A electrically connected to the top pad 130, and the conductive pattern 120A may be exposed to the outside through the sidewall 150.

In some example embodiments, as described below, when fabricating a semiconductor package, multiple semiconductor chips 100A may be electrically connected to each other by using a printed pattern instead of bonding wires. According to some example embodiments, when fabricating the semiconductor package, the multiple semiconductor chips 100A may be mounted on the substrate to allow the conductive patterns 120A to face the substrate. Accordingly, the semiconductor package according to the present disclosure may be implemented as a high-capacity package while providing improved operational reliability.

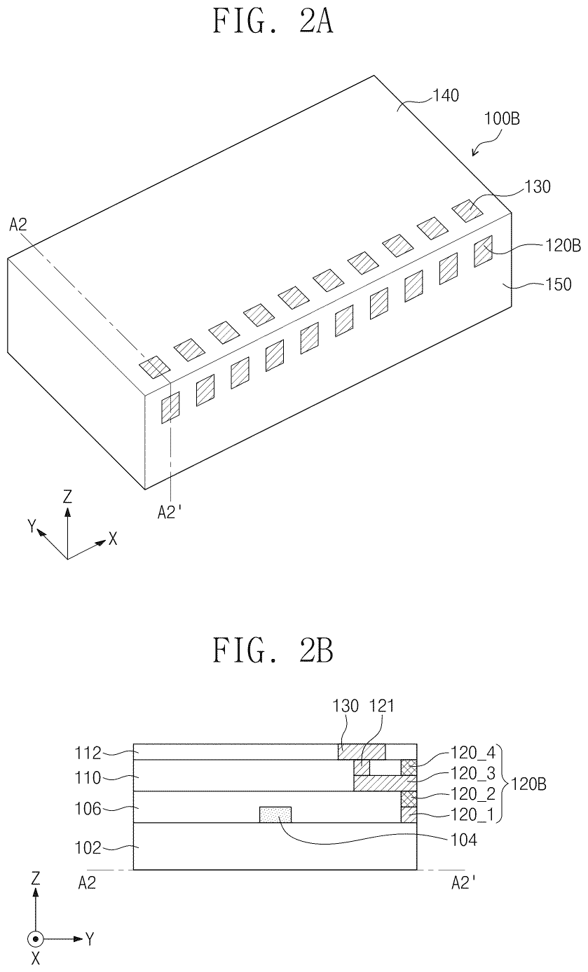

FIG. 2A is a perspective view illustrating a semiconductor chip 100B according to some example embodiments of the present disclosure. FIG. 2B is a cross-sectional view taken along a line A2-A2′ of FIG. 2A.

The semiconductor chip 100B of FIGS. 2A and 2B is similar to the semiconductor chip 100A of FIGS. 1A and 1B. Accordingly, details of the semiconductor chip 100B, which are identical to those of the semiconductor chip 100A, will be omitted.

Referring to FIGS. 2A and 2B, the semiconductor chip 100B may include a top pad 130 disposed on an upper surface 140 and a side pad 120B exposed through a sidewall 150, and the top pad 130 may be electrically connected to the side pad 120B.

For example, a first conductive pattern 120_1 may be formed on a substrate 102. The first conductive pattern 120_1 may be exposed to the outside through the sidewall 150. As an example, the first conductive pattern 120_1 may include aluminum, copper, tungsten, molybdenum, and a conductive material such as titanium nitride, tantalum nitride, or tungsten nitride. However, this is merely an example, and the first conductive pattern 120_1 may include a variety of materials.

A first interlayer insulating layer 106 may be formed to cover the substrate 102 on which a conductive area 104 and a first conductive pattern 120_1 are formed.

A first buried conductive pattern 120_2 may be formed on the first conductive pattern 120_1. As an example, a portion of the first interlayer insulating layer 106 may be removed by an etching process, and thus, an upper surface of the first conductive pattern 120_1 may be exposed. Then, the removed portion of the first interlayer insulating layer 106 may be filled with the first buried conductive pattern 120_2. The first buried conductive pattern 120_2 may have the same width as the first conductive pattern 120_1, however, the present disclosure should not be limited thereto or thereby.

A second conductive pattern 120_3 may be formed on the first interlayer insulating layer 106. The second conductive pattern 120_3 may extend in the second direction (Y direction), and a portion of the second conductive pattern 120_3 may overlap the top pad 130 when viewed in the horizontal direction. The second conductive pattern 120_3 may be exposed to the outside through the sidewall 150. The second conductive pattern 120_3 may include the same conductive material as the first conductive pattern 120_1.

A second interlayer insulating layer 110 may be formed to cover the first interlayer insulating layer 106 and the second conductive pattern 120_3.

A second buried conductive pattern 120_4 may be formed on the second conductive pattern 120_3. As an example, a portion of the second interlayer insulating layer 110 may be removed by an etching process, and thus, a portion of an upper surface of the second conductive pattern 120_3 may be exposed. Then, the removed portion of the second interlayer insulating layer 110 may be filled with the second buried conductive pattern 120_4.

The top pad 130 may be formed on the second interlayer insulating layer 110, however, this is merely an example. According to some example embodiments, the top pad 130 may be formed on a protective layer 112.

The protective layer 112 may be formed to cover the second interlayer insulating layer 110 and the top pad 130.

A metal contact 121 may be formed to electrically connect the top pad 130 and the second conductive pattern 120_3. As an example, the metal contact 121 may be a through-hole via (THV). According to some example embodiments, the metal contact 121 may include a conductive material such as a metal, a metal compound, or doped polysilicon.

As described with reference to FIGS. 2A and 2B, the semiconductor chip 100B according to the present disclosure may include the top pad 130 and the side pad 120B electrically connected to the top pad 130, and the side pad 120B may be exposed to the outside through the sidewall 150. In some example embodiments, the side pad 120B may include a plurality of conductive patterns and/or buried conductive patterns.

In some example embodiments, as described below, when fabricating a semiconductor package, semiconductor chips 100B may be electrically connected to each other by using a printed pattern instead of bonding wires. According to some example embodiments, when fabricating the semiconductor package, the semiconductor chips 100B may be mounted on the substrate to allow the side pads to face the substrate. Accordingly, the semiconductor package according to the present disclosure may be implemented as a high-capacity package while providing improved operational reliability.

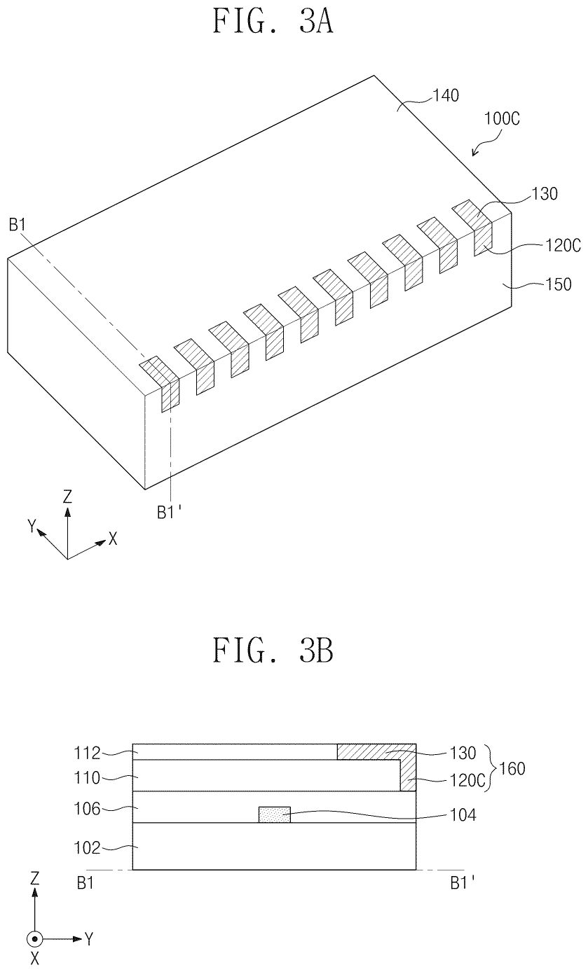

FIG. 3A is a perspective view illustrating a semiconductor chip 100C according to some example embodiments of the present disclosure. FIG. 3B is a cross-sectional view taken along a line B1-B1′ of FIG. 3A.

The semiconductor chip 100C of FIGS. 3A and 3B is similar to the semiconductor chips 100A and 100B of FIGS. 1A to 2B. Accordingly, details of the semiconductor chip 100C, which are identical to those of the semiconductor chips 100A and 100B, will be omitted.

Referring to FIGS. 3A and 3B, the semiconductor chip 100C may include a top pad 130 and a side pad 120C, and the top pad 130 and the side pad 120C may be formed integrally with each other as a metal layer 160.

For example, a conductive area 104 may be formed on a substrate 102.

A first interlayer insulating layer 106 may be formed to cover the substrate 102 on which the conductive area 104 is formed.

A second interlayer insulating layer 110 may be formed to cover the first interlayer insulating layer 106.

A protective layer 112 may be formed to cover the second interlayer insulating layer 110.

The metal layer 160 may be formed on an upper surface of the second interlayer insulating layer 110 and an upper surface of the first interlayer insulating layer 106. As an example, a portion of the upper surface of the second interlayer insulating layer 110 and a portion of the upper surface of the first interlayer insulating layer 106 may be exposed through an etching process. The metal layer 160 may be formed on the exposed portion of the upper surface of the second interlayer insulating layer 110 and the exposed portion of the upper surface of the first interlayer insulating layer 106. As an example, the metal layer 160 may be formed through a plating process, and the metal layer 160 may include a conductive material such as copper.

According to some example embodiments, the metal layer 160 may be formed by first forming a seed layer and then performing an electroplating process on the seed layer. After the seed layer is formed through a palladium (Pd) treatment and/or an electroless plating process, a copper electroplating process may be carried out on top of the seed layer, and thus, the metal layer 160 may be formed.

A portion 130 of the metal layer 160, which is exposed through an upper surface 140, may be referred to as the top pad, and a portion 120C of the metal layer 160, which is exposed through a sidewall 150, may be referred to as the side pad or a pad conductive pattern.

As described with reference to FIGS. 3A and 3B, the semiconductor chip 100C according to the present disclosure may include the top pad 130 and the side pad 120C, and the top pad 130 and the side pad 120C may be formed integrally with each other as the metal layer 160.

In some example embodiments, as described below, when fabricating a semiconductor package, multiple semiconductor chips 100C may be electrically connected to each other by using a printed pattern instead of bonding wires. According to some example embodiments, when fabricating the semiconductor package, the multiple semiconductor chips 100C may be mounted on the substrate to allow the side pads 120C to face the substrate. Accordingly, the semiconductor package according to the present disclosure may be implemented as a high-capacity package while providing improved operational reliability.

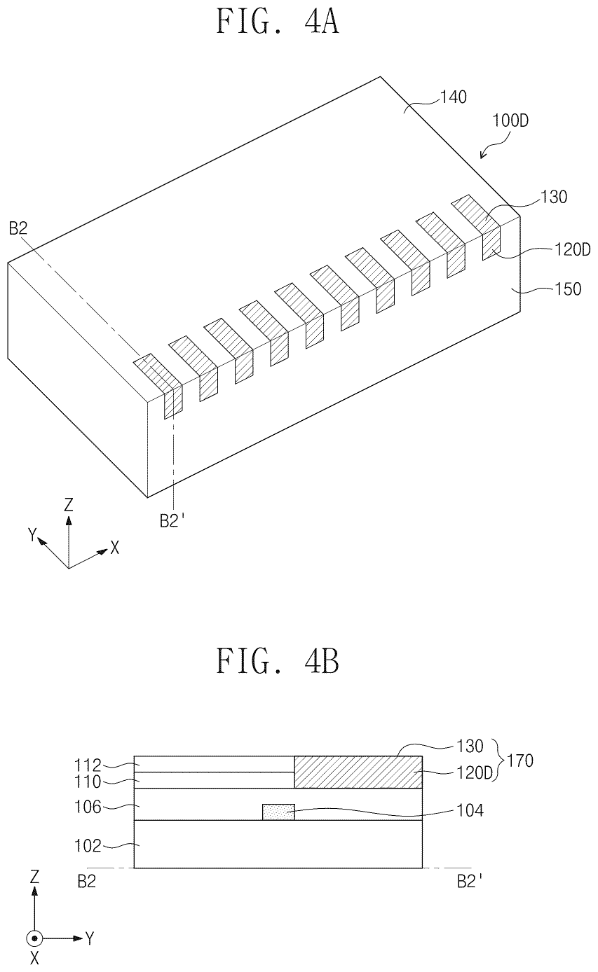

FIG. 4A is a perspective view illustrating a semiconductor chip 100D according to some example embodiments of the present disclosure. FIG. 4B is a cross-sectional view taken along a line B2-B2′ of FIG. 4A.

The semiconductor chip 100D of FIGS. 4A and 4B is similar to the semiconductor chips 100A, 100B, and 100C of FIGS. 1A to 3B. Accordingly, details of the semiconductor chip 100D, which are identical to those of the semiconductor chips 100A, 100B, and 100C, will be omitted.

Referring to FIGS. 4A and 4B, the semiconductor chip 100D may include a conductive pattern 170, and the conductive pattern 170 may be formed on a first interlayer insulating layer 106, however, this is merely an example. According to some example embodiments, the conductive pattern 170 may be formed on a second interlayer insulating layer 110 or may be formed on a protective layer 112.

A portion of the conductive pattern 170 may be exposed to the outside through an upper surface 140, and the other portion of the conductive pattern 170 may be exposed to the outside through a sidewall 150. The portion of the conductive pattern 170, which is exposed through the upper surface 140, may correspond to a top pad 130, and the portion of the conductive pattern 170, which is exposed through the sidewall 150, may correspond to a side pad 120D.

In some example embodiments, as described below, when fabricating a semiconductor package, multiple semiconductor chips 100D may be electrically connected to each other by using a printed pattern instead of bonding wires. According to some example embodiments, when fabricating the semiconductor package, the multiple semiconductor chips 100D may be mounted on a substrate to allow the side pads 120D to face the substrate. Accordingly, the semiconductor package according to the present disclosure may be implemented as a high-capacity package while providing improved operational reliability.

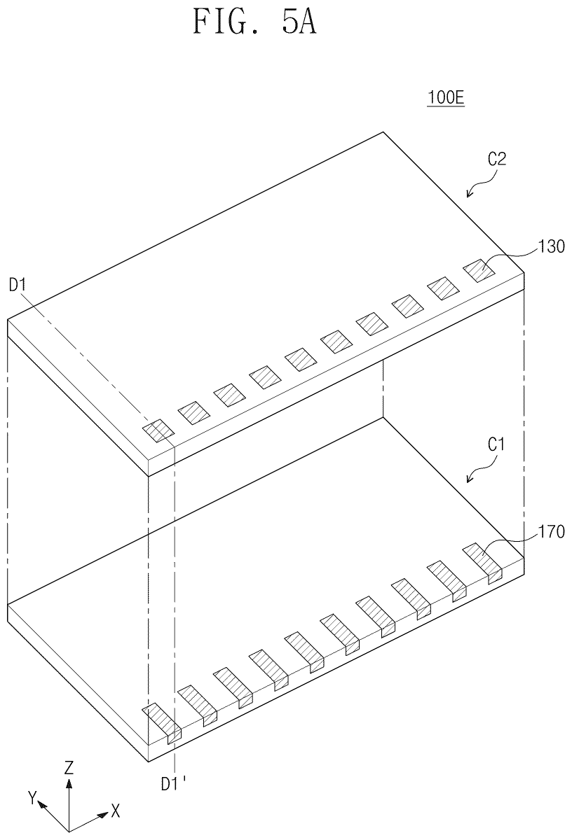

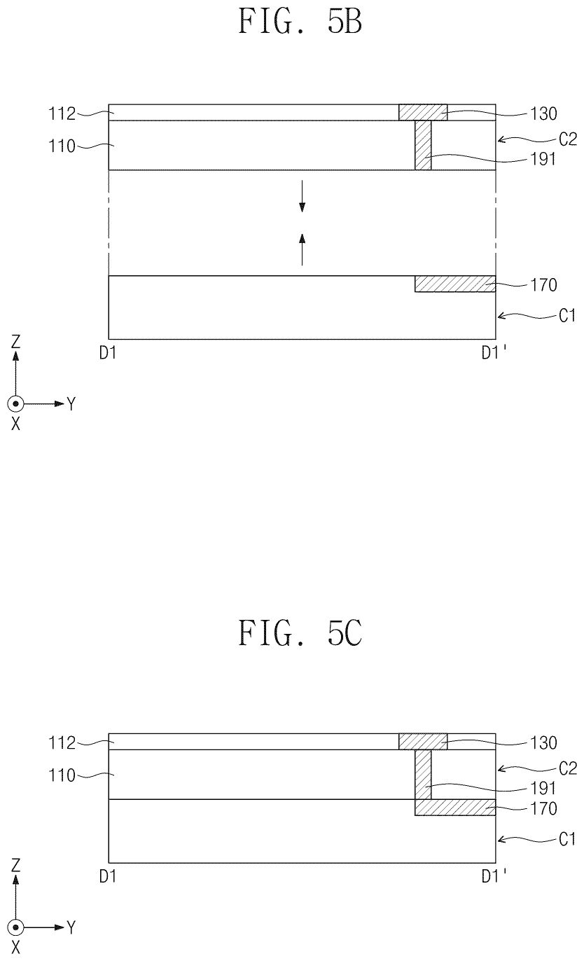

FIGS. 5A to 5C are views illustrating a semiconductor chip 100E according to some example embodiments of the present disclosure. For example, FIG. 5A shows an example in which two chips are bonded to form the semiconductor chip 100E. FIG. 5B shows a process of bonding the two chips in a cross-section taken along a line D1-D1′ of FIG. 5A. FIG. 5C shows a cross-section taken along the line D1-D1′ of FIG. 5A.

The semiconductor chip 100E of FIGS. 5A to 5C is similar to the semiconductor chips 100A, 100B, 100C, and 100D of FIGS. 1A to 4B. Accordingly, details of the semiconductor chip 100E, which are identical to those of the semiconductor chips 100A, 100B, 100C, and 100D, will be omitted.

Referring to FIGS. 5A to 5C, the semiconductor chip 100E may be formed by stacking a first chip C1 and a second chip C2 in a vertical direction.

A conductive pattern 170 may be formed in the first chip C1, and each of upper and side surfaces of the conductive pattern 170 may be exposed to the outside. As an example, the first chip C1 may be implemented by the semiconductor chip 100D of FIGS. 4A and 4B, and the conductive pattern 170 of the first chip C1 may be the conductive pattern 170 of FIGS. 4A and 4B, however, this is merely an example. According to some example embodiments, the first chip C1 may be implemented by the semiconductor chips 100A, 100B, 100C, and 100D of FIGS. 1A to 4B each including the top pad and the side pad.

A top pad 130 may be formed in the second chip C2, and the top pad 130 may be exposed to the outside through an upper surface of the second chip C2. The top pad 130 of the second chip C2 may be electrically connected to a metal contact 191. The metal contact 191 may be exposed to the outside through a lower surface of the second chip C2. As an example, the metal contact 191 may be a through-hole via (THV). According to some example embodiments, the metal contact 191 may include a conductive material such as a metal, a metal compound, or doped polysilicon.

The first chip C1 and the second chip C2 may be connected to each other by a bonding method. In some example embodiments, the bonding method may refer to a method of electrically connecting the conductive pattern 170 of the first chip C1 and the metal contact 191 of the second chip C2. As an example, where the conductive pattern 170 of the first chip C1 and the metal contact 191 of the second chip C2 are formed of copper (Cu), the bonding method may be a Cu—Cu bonding method.

Since the first chip C1 and the second chip C2 are bonded to each other, the semiconductor chip 100E that includes the top pad 130 and the conductive pattern 170 electrically connected to the top pad 130 may be formed.

In some example embodiments, the conductive pattern 170 may be exposed through a side surface of the semiconductor chip 100E. Accordingly, as described below, when fabricating a semiconductor package, multiple semiconductor chips 100E may be electrically connected to each other by using a printed pattern instead of bonding wires. According to some example embodiments, when fabricating the semiconductor package, the multiple semiconductor chips 100E may be mounted on a substrate to allow the conductive patterns 170 to face the substrate. Accordingly, the semiconductor package according to the present disclosure may be implemented as a high-capacity package while providing improved operational reliability.

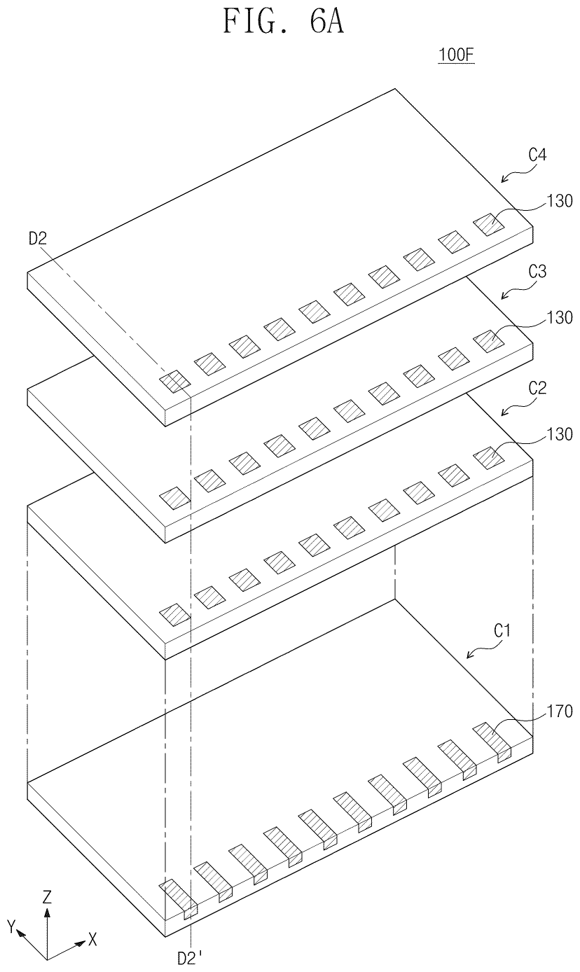

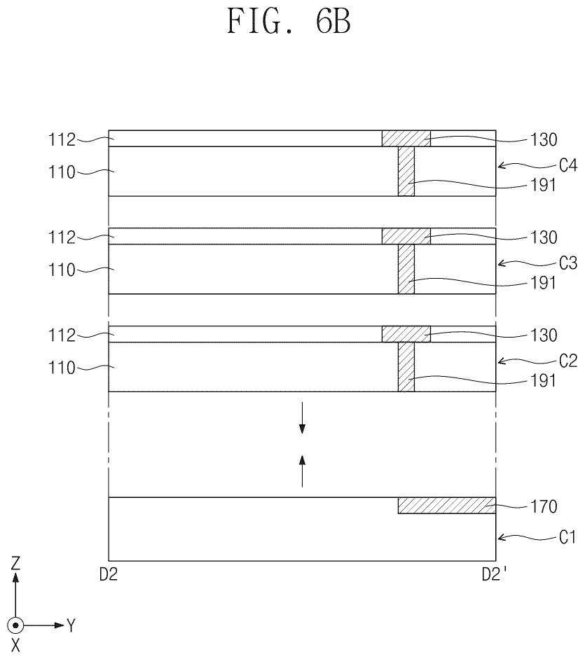

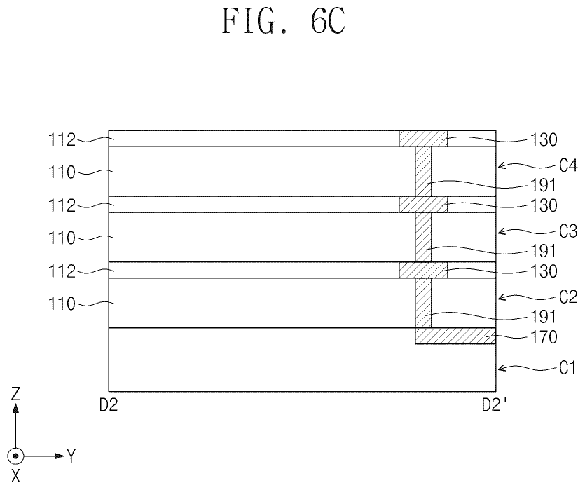

FIGS. 6A to 6C are views illustrating a semiconductor chip 100F according to some example embodiments of the present disclosure. For example, FIG. 6A shows an example in which multiple chips are bonded to form the semiconductor chip 100F. FIG. 6B shows a process of bonding the multiple chips in a cross-section taken along a line D2-D2′ of FIG. 6A. FIG. 6C shows a cross-section taken along the line D2-D2′ of FIG. 6A.

The semiconductor chip 100F of FIGS. 6A to 6C is similar to the semiconductor chips 100A, 100B, 100C, 100D, and 100E of FIGS. 1A to 5C. Accordingly, details of the semiconductor chip 100F, which are identical to those of the semiconductor chips 100A, 100B, 100C, 100D, and 100E, will be omitted.

Referring to FIGS. 6A to 6C, the semiconductor chip 100F may be formed by stacking multiple chips in a vertical direction. As an example, FIGS. 6A to 6C show the structure in which four chips are stacked in the vertical direction.

A conductive pattern 170 may be formed in a first chip C1, and each of upper and side surfaces of the conductive pattern 170 may be exposed to the outside. As an example, the first chip C1 may be implemented by the semiconductor chip 100D of FIGS. 4A and 4B, however, this is merely an example. According to some example embodiments, the first chip C1 may be implemented by the semiconductor chips 100A, 100B, 100C, and 100D of FIGS. 1A to 4B, each including the top pad and the side pad.

A top pad 130 may be formed in each of second to fourth chips C2 to C4, and the top pad 130 may be exposed to the outside. The top pad 130 of each of the second to fourth chips C2 to C4 may be electrically connected to a corresponding metal contact 191. The metal contact 191 may be exposed to the outside through a lower surface of each of the second to fourth chips C2 to C4.

The first to fourth chips C1 to C4 may be connected to each other by a bonding method. As the first to fourth chips C1 to C4 are bonded to each other, the semiconductor chip 100F may be formed. The top pad 130 of the fourth chip C4 may be exposed through an upper surface of the semiconductor chip 100F, the conductive pattern 170 of the first chip C1 may be exposed to the outside through a side surface of the semiconductor chip 100F, and the top pad 130 of the fourth chip C4 and the conductive pattern 170 of the first chip C1 may be electrically connected to each other.

Accordingly, as described below, when fabricating a semiconductor package, multiple semiconductor chips 100F may be electrically connected to each other by using a printed pattern instead of bonding wires. According to some example embodiments, when fabricating the semiconductor package, the multiple semiconductor chips 100F may be mounted on a substrate to allow the conductive patterns 170 to face the substrate. Accordingly, the semiconductor package according to the present disclosure may be implemented as a high-capacity package while providing improved operational reliability.

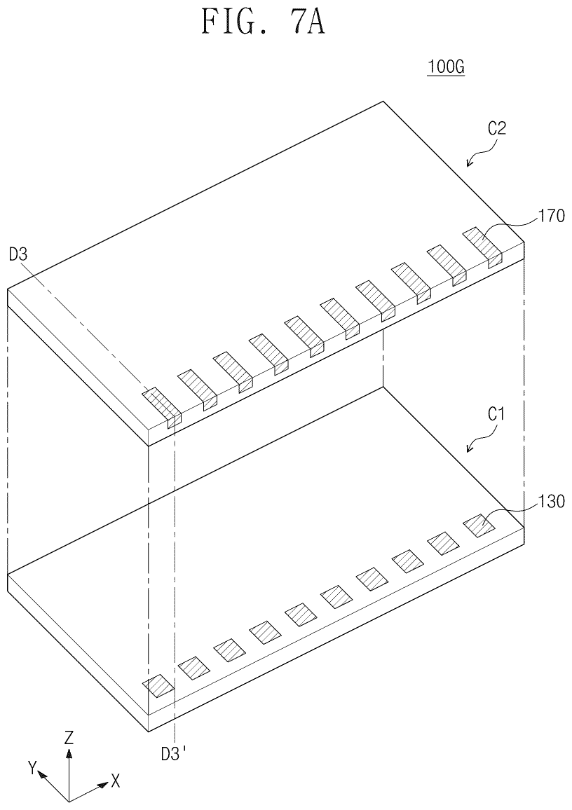

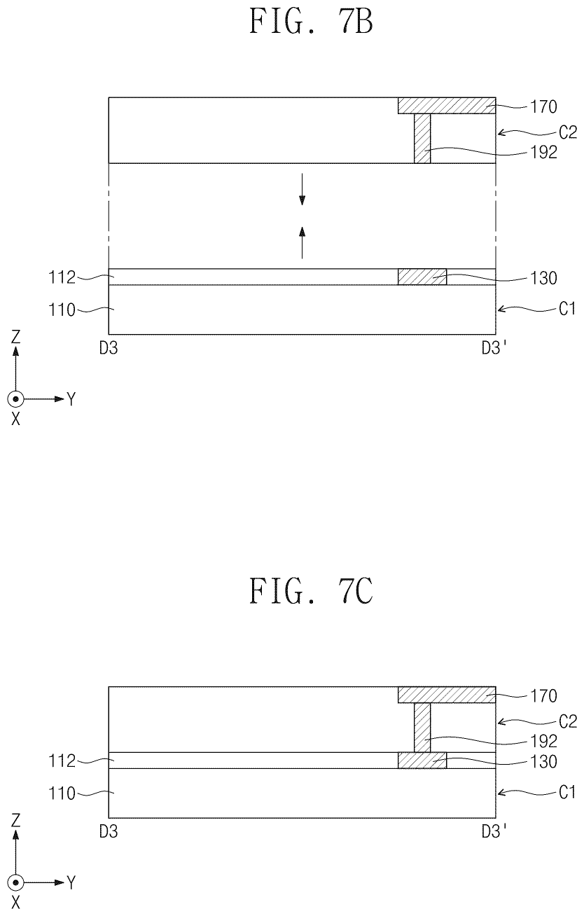

FIGS. 7A to 7C are views illustrating a semiconductor chip 100G according to some example embodiments of the present disclosure. For example, FIG. 7A shows an example in which two chips are bonded to form the semiconductor chip 100G. FIG. 7B shows a process of bonding the two chips in a cross-section taken along a line D3-D3′ of FIG. 7A. FIG. 7C shows a cross-section taken along the line D3-D3′ of FIG. 7A.

The semiconductor chip 100G of FIGS. 7A to 7C is similar to the semiconductor chips 100A, 100B, 100C, 100D, 100E, and 100F of FIGS. 1A to 6C. Accordingly, details of the semiconductor chip 100G, which are identical to those of the semiconductor chips 100A, 100B, 100C, 100D, 100E, and 100F, will be omitted.

Referring to FIGS. 7A to 7C, the semiconductor chip 100G may be formed by stacking a first chip C1 and a second chip C2 in a vertical direction. In some example embodiments, the first chip C1 may be a general semiconductor chip including a top pad 130. The second chip C2 may be a semiconductor chip including a top pad and a side pad.

As an example, the top pad 130 may be formed in the first chip C1, and the top pad 130 may be exposed to the outside through an upper surface of the semiconductor chip C1. The second chip C2 may include a conductive pattern 170, a portion of the conductive pattern 170 may be exposed to the outside through an upper surface of the second chip C2, and a portion of the conductive pattern 170 may be exposed to the outside through a side surface of the second chip C2. A metal contact 192 may be formed in the second chip C2, and the metal contact 192 may electrically connect the conductive pattern 170 of the second chip C2 and the top pad 130 of the first chip C1.

In some example embodiments, as described below, when fabricating a semiconductor package, multiple semiconductor chips 100G may be electrically connected to each other by using a printed pattern instead of bonding wires. According to some example embodiments, when fabricating the semiconductor package, the multiple semiconductor chips 100G may be mounted on a substrate to allow the conductive patterns 170 to face the substrate. Accordingly, the semiconductor package according to the present disclosure may be implemented as a high-capacity package while providing improved operational reliability.

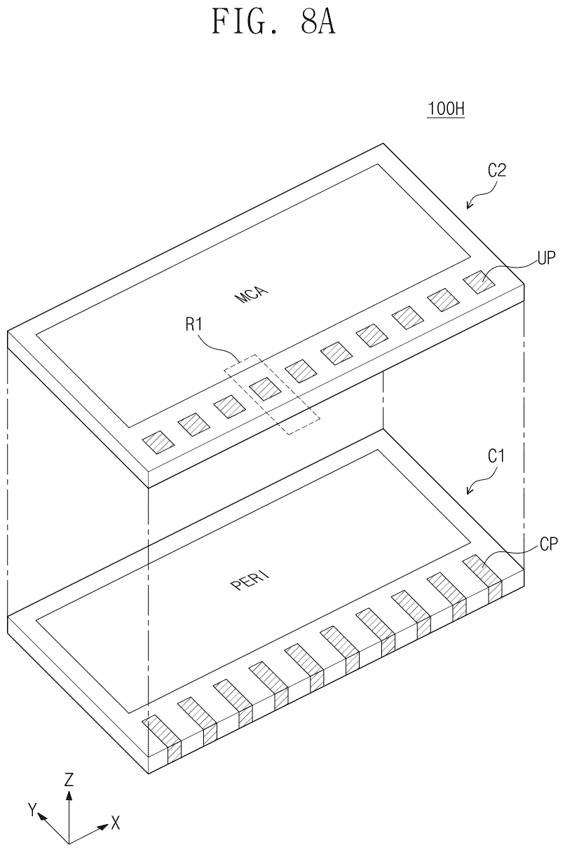

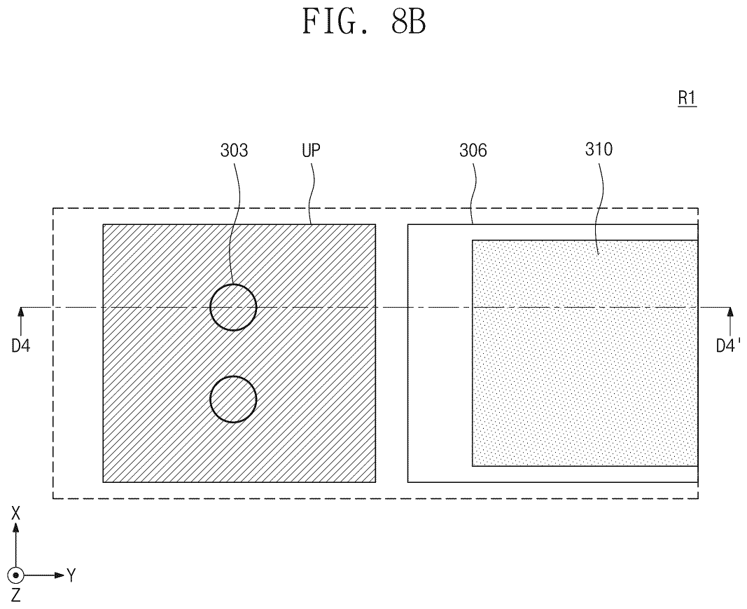

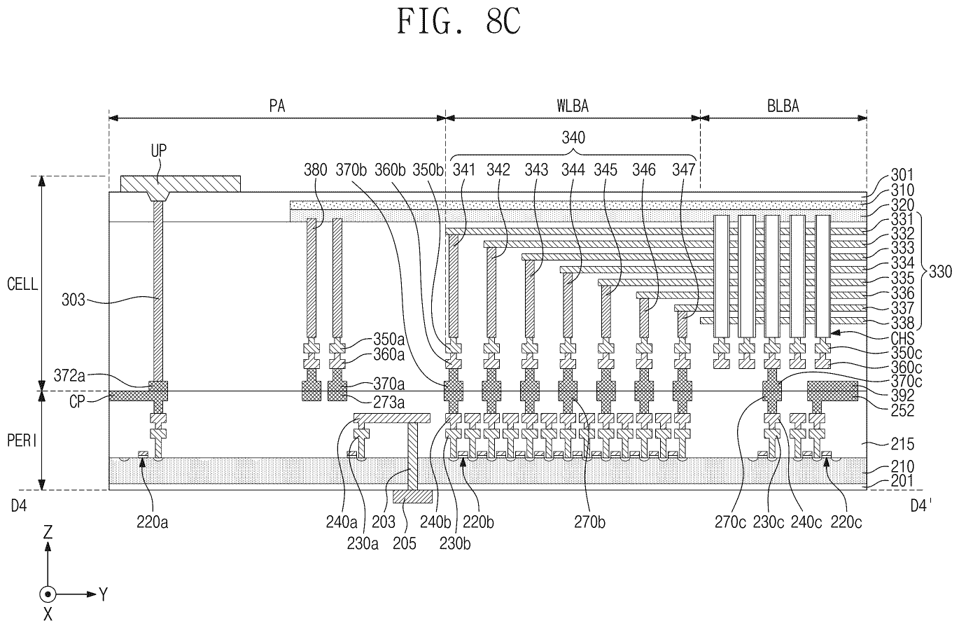

FIGS. 8A to 8C are views illustrating a semiconductor chip 100H formed by vertically stacking multiple chips according to some example embodiments of the present disclosure. In more detail, FIG. 8A shows the semiconductor chip 100H according to some example embodiments of the present disclosure. FIG. 8B is a plan view illustrating in detail a first region R1 of FIG. 8A. FIG. 8C is a cross-sectional view taken along a line D4-D4′ of FIG. 8B.

The semiconductor chip 100H of FIGS. 8A to 8C is similar to the semiconductor chips 100A, 100B, 100C, 100D, 100E, 100F, and 100G of FIGS. 1A to 7C. Accordingly, details of the semiconductor chip 100H, which are identical to those of the semiconductor chips 100A, 100B, 100C, 100D, 100E, 100F, and 100G, will be omitted. For the convenience of explanation, in FIGS. 8A to 8C, it is assumed that the semiconductor chip 100H is implemented to include a NAND flash memory, however, this is merely an example. According to some example embodiments, the semiconductor chip 100H may be implemented to include a volatile memory such as DRAM, SRAM, etc., or a non-volatile memory such as MRAM, RRAM, etc.

Referring to FIG. 8A, the semiconductor chip 100H may include first and second chips C1 and C2 stacked in a vertical direction.

The first chip C1 may include a peripheral circuit PERI such as a row decoder, a page buffer, etc. The second chip C2 may include a memory cell array MCA including NAND flash memories. The first chip C1 and the second chip C2 may be connected to each other by a bonding method.

Top pads UP may be arranged at at least one side of memory cell arrays MCA. As an example, the top pads UP may be arranged in a row along at least one edge of the second chip C2, however, this is merely an example. According to some example embodiments, the top pads UP may be arranged in various ways.

Conductive patterns CP may be arranged at at least one side of the peripheral circuit PERI. As an example, the conductive patterns CP may be arranged in a row along at least one edge of the first chip C1. For example, each of the conductive patterns CP may be disposed to allow at least a portion thereof to overlap a corresponding top pad UP, however, this is merely an example. According to some example embodiments, the conductive patterns CP may be arranged in various ways.

One end of the conductive patterns CP may be exposed to the outside through a sidewall of the first chip C1. The conductive pattern CP exposed through the sidewall of the first chip C1 may be used as a side pad, and thus, the conductive pattern CP may be referred to as a pad conductive pattern or the side pad.

Referring to FIGS. 8A, 8B, and 8C, the semiconductor chip 100H may have a chip-to-chip (C2C) structure. In the some example embodiments, the C2C structure may refer to a structure obtained by manufacturing at least one upper chip that includes a cell area CELL and a lower chip that includes a peripheral circuit area PERI and then connecting the at least one upper chip and the lower chip to each other by a bonding method.

As an example, the bonding method may refer to a process of electrically connecting a bonding metal pattern formed on a top metal layer of the upper chip and a bonding metal pattern formed on a top metal layer of the lower chip. As an example, when the bonding metal patterns include copper (Cu), the bonding method may be a Cu—Cu bonding method. According to some example embodiments, the bonding metal patterns may include aluminum (Al) or tungsten (W).

The semiconductor chip 100H may include one or more upper chips including the cell area. As an example, as shown in FIGS. 8A to 8C, the semiconductor chip 100D may include one upper chip, however, this is merely an example, and the number of the upper chip should not be particularly limited. In the following descriptions, upper and lower portions of the upper chip are defined based on its orientation before the upper chip is inverted. For example, an upper portion of the lower chip refers to an upper portion defined based on a positive (+) Z-axis direction, and the upper portion of the upper chip refers to an upper portion defined based on a negative (−) Z-axis direction.

Each of the peripheral circuit area PERI and the cell area CELL of the semiconductor chip 100D may include an external pad bonding area PA, a word line bonding area WLBA, and a bit line bonding area BLBA.

The peripheral circuit area PERI may include a first substrate 210 and multiple circuit elements 220a, 220b, and 220c formed on the first substrate 210. An interlayer insulating layer 215 including one or more insulating layers may be provided on the multiple circuit elements 220a, 220b, and 220c, and multiple metal wires may be provided in the interlayer insulating layer 215 to connect the multiple circuit elements 220a, 220b, and 220c. As an example, the multiple metal wires may include a first metal wire 230a, 230b, and 230c connected to each of the circuit elements 220a, 220b, and 220c and a second metal wire 240a, 240b, and 240c formed on the first metal wire 230a, 230b, and 230c. The multiple metal wires may include at least one of various conductive materials. As an example, the first metal wire 230a, 230b, and 230c may include tungsten, which has a relatively high electrical resistivity, and the second metal wire 240a, 240b, and 240c may include copper, which has a relatively low electrical resistivity.

In the present disclosure, only the first metal wire 230a, 230b, and 230c and the second metal wire 240a, 240b, and 240c are shown and described, however, the present disclosure should not be limited thereto or thereby. According to some example embodiments, one or more additional metal wires may further be formed on the second metal wire 240a, 240b, and 240c. In some example embodiments, the second metal wire 240a, 240b, and 240c may include aluminum. At least a portion of the additional metal wires formed on the second metal wire 240a, 240b, and 240c may include copper, which has a relatively low electrical resistivity compared to aluminum of the second metal wire 240a, 240b, and 240c.

The interlayer insulating layer 215 may be disposed on the first substrate 210 and may include an insulating material such as silicon oxide, silicon nitride, and the like.

The cell area CELL may include at least one memory block. The cell area CELL may include a common source line 310 having a plate shape extending in the first direction (X direction) and the second direction (Y direction). The common source line 310 may include a metal material, for example, tungsten (W), aluminum (Al), copper (Cu), tungsten nitride (WN), tantalum nitride (TaN), titanium nitride (TiN), or combinations thereof.

A second substrate 320 may be formed on the common source line 310. In some example embodiments, the second substrate 320 may include a material different from that of the first substrate 210. As an example, the second substrate 320 may be provided as a polycrystalline layer or an epitaxial layer, or may include a doped region containing impurities, however, the present disclosure should not be limited thereto or thereby. According to some example embodiments, the second substrate 320 may be omitted, and only the common source line 310 may be provided. According to some example embodiments, only the second substrate 320 may be provided without the common source line 310, and in some example embodiments, the second substrate 320 may perform a function of the common source line. Hereinafter, for the convenience of explanation, it is assumed that the common source line 310 and the second substrate 320 overlapping the common source line 310 function together as the common source line.

Multiple word lines 330, e.g., 331 to 338, may be stacked on the second substrate 320 in a direction (Z-axis direction) perpendicular to an upper surface of the second substrate 320. String selection lines and a ground selection line may be arranged above and below the word lines 330, respectively, and the word lines 330 may be arranged between the string selection lines and the ground selection line.

In the bit line bonding area BLBA, a channel structure CHS may extend in the direction (Z-axis direction) perpendicular to an upper surface of the common source line 310 and may penetrate the word lines 330, the string selection lines, and the ground selection line. The channel structure CHS may include a data storage layer, a channel layer, and a buried insulating layer, and the channel layer may be electrically connected to a first metal wire 350c and a second metal wire 360c. As an example, the second metal wire 360c may be a bit line and may be connected to the channel structure CHS through the first metal wire 350c. According to some example embodiments, the bit line 360c may extend in the first direction (X direction) parallel to the upper surface of the common source line 310.

In the bit line bonding area BLBA, an upper metal pattern 252 may be formed in a top metal layer of the peripheral circuit area PERI, and an upper metal pattern 392 having the same shape as the upper metal pattern 252 may be formed in a top metal layer of the cell area CELL. The upper metal pattern 392 of the cell area CELL and the upper metal pattern 252 of the peripheral circuit area PERI may be electrically connected to each other by a bonding method. In the bit line bonding area BLBA, the bit line 360c may be electrically connected to the page buffer included in the peripheral circuit area PERI. As an example, some of the circuit elements 220c of the peripheral circuit area PERI may provide the page buffer, and the bit line 360c may be electrically connected to the circuit elements 220c, which provide the page buffer, through an upper bonding metal 370c of the cell area CELL and an upper bonding metal 270c of the peripheral circuit area PERI.

Referring to FIGS. 8A to 8C, in the word line bonding area WLBA, the word lines 330 of the cell area CELL may extend in the second direction (Y direction) parallel to the upper surface of the common source line 310 and may be connected to multiple cell contact plugs 340, e.g., 341 to 347. A first metal wire 350b and a second metal wire 360b may be sequentially connected to upper portions of the cell contact plugs 340 connected to the word lines 330. The cell contact plugs 340 may be connected to the peripheral circuit area PERI in the word line bonding area WLBA through an upper bonding metal 370b of the cell area CELL and an upper bonding metal 270b of the peripheral circuit area PERI.

The cell contact plugs 340 may be electrically connected to the row decoder included in the peripheral circuit area PERI. As an example, some of the circuit elements 220b of the peripheral circuit area PERI may provide the row decoder, and the cell contact plugs 340 may be electrically connected to the circuit elements 220b, which provide the row decoder, through the upper bonding metal 370b of the cell area CELL and the upper bonding metal 270b of the peripheral circuit area PERI. According to some example embodiments, an operating voltage of the circuit elements 220b, which provide the row decoder, may be different from an operating voltage of the circuit elements 220c, which provide the page buffer. As an example, the operating voltage of the circuit elements 220c, which provide the page buffer may be higher than the operating voltage of the circuit elements 220b, which provide the row decoder.

In the external pad bonding area PA, common source line contact plugs 380 may be arranged in the direction (Z-axis direction) perpendicular to the upper surface of the common source line 310 of the cell area CELL. The common source line contact plugs 380 may include a conductive material, such as a metal, a metal compound, or doped polysilicon. The common source line contact plug 380 of the cell area CELL may be electrically connected to the common source line 310. A first metal wire 350a and a second metal wire 360a may be sequentially stacked on the common source line contact plug 380 of the cell area CELL. The common source line contact plug 380 may be connected to the peripheral circuit area PERI through an upper bonding metal 370a of the cell area CELL and the upper bonding metal 273a of the peripheral circuit area PERI.

According to some example embodiments, in the external pad bonding area PA, a lower insulating layer 201 may be formed under the first substrate 210 to cover a lower surface of the first substrate 210, and a first input/output pad 205 may be formed on the lower insulating layer 201. The first input/output pad 205 may be connected to at least one of the circuit elements 220a, 220b, and 220c arranged in the peripheral circuit area PERI through a first input/output contact plug 203 and may be separated from the first substrate 210 by the lower insulating layer 201. A side surface insulating layer may be disposed between the first input/output contact plug 203 and the first substrate 210 to electrically insulate the first input/output contact plug 203 from the first substrate 210, however, the present disclosure should not be limited thereto or thereby. According to some example embodiments, the first input/output pad 205 may not be provided.

In the external pad bonding area PA, an upper insulating layer 301 may be formed on a lower surface of the common source line 310 to cover the lower surface of the common source line 310, and a top pad UP may be disposed on a lower surface of the upper insulating layer 301.

The top pad UP may be used as an input/output pad. For example, a second input/output contact plug 303 may penetrate the upper insulating layer 301 and may be electrically connected to the top pad UP that is a second input/output pad, and the top pad UP may be connected to at least one of the multiple circuit elements 220a, 220b, and 220c arranged in the peripheral circuit area PERI through the second input/output contact plug 303.

In the external pad bonding area PA, an upper metal pattern 372a may be formed at the upper portion of the cell area CELL, and an upper metal pattern CP may be formed at the upper portion of the peripheral circuit area PERI. The upper metal pattern 372a of the cell area CELL and the upper metal pattern CP of the peripheral circuit area PERI may be connected to each other by a bonding method.

In the present disclosure, the upper metal pattern CP of the peripheral circuit area PERI may be exposed to the outside through a sidewall. For example, the upper metal pattern CP of the peripheral circuit area PERI may be implemented as a pad conductive pattern or a side pad, however the present disclosure should not be limited thereto or thereby. According to some example embodiments, the upper metal pattern 372a of the cell area CELL may be exposed to the outside through the sidewall and may be implemented as the side pad. According to some example embodiments, both the upper metal pattern CP of the peripheral circuit area PERI and the upper metal pattern 372a of the cell area CELL may be exposed to the outside through the sidewall and may be implemented as the side pad.

As described with reference to FIGS. 8A to 8C, the semiconductor chip 100H according to the some example embodiments may be implemented in the C2C structure. In some example embodiments, the semiconductor chip 100H may include the top pad UP and the metal pattern CP electrically connected to the top pad, and the metal pattern CP may be exposed to the outside through the sidewall. Accordingly, the semiconductor chips 100H may be electrically connected to each other by using a printed pattern instead of bonding wires, or the metal pattern CP may be directly connected to a substrate pad on the substrate. Therefore, the semiconductor package according to the present disclosure may be implemented as a high-capacity package while providing improved operational reliability.

### <A Semiconductor Package in Which Semiconductor Chips Including a Side Pad are Stacked>

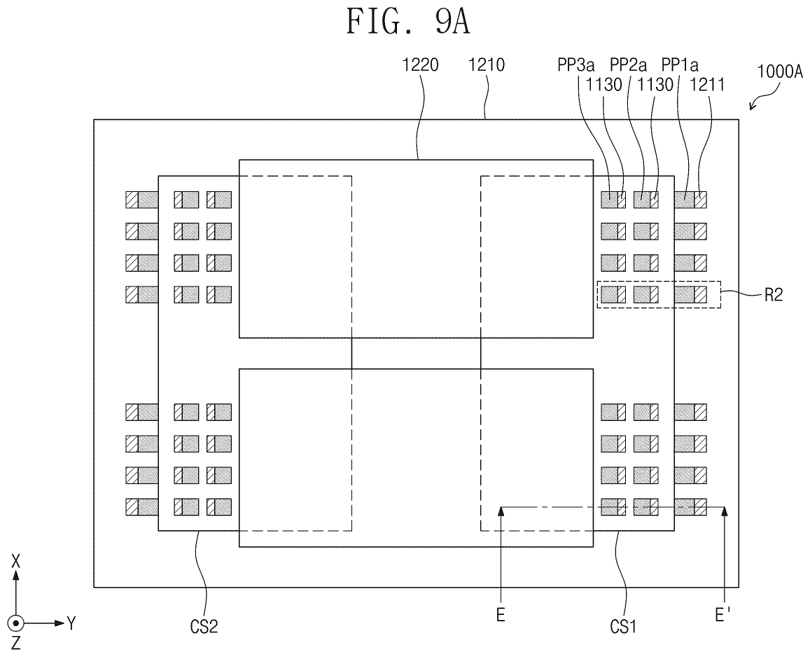

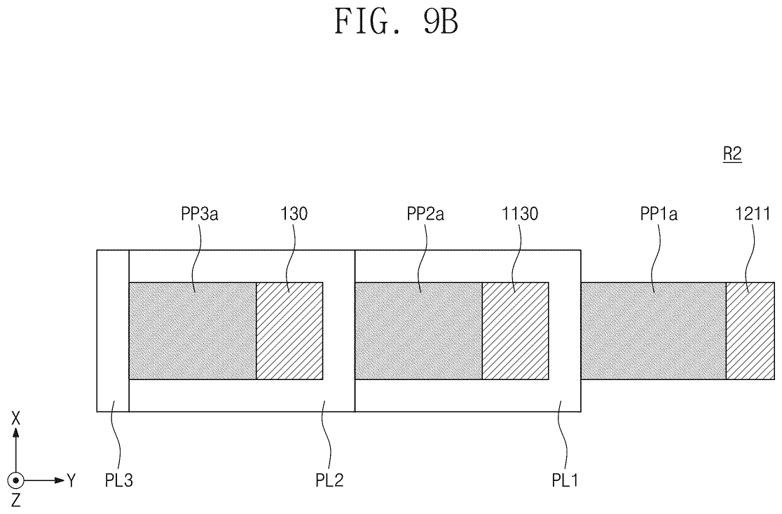

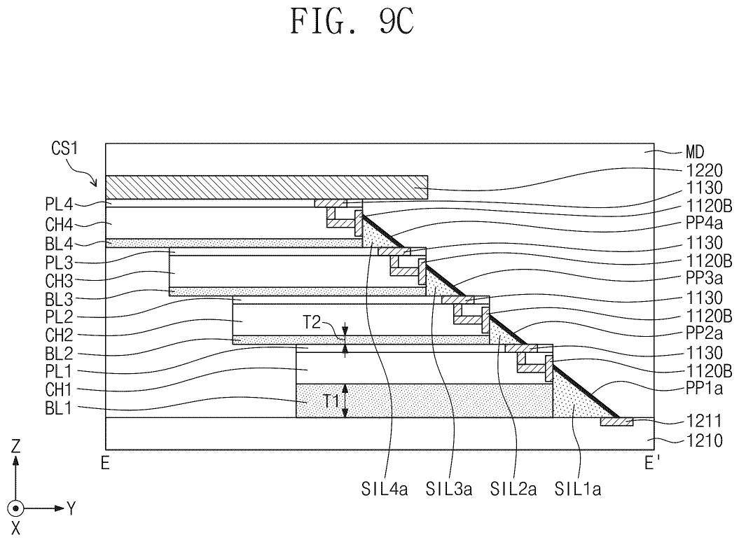

FIG. 9A is a plan view illustrating a semiconductor package 1000A according to some example embodiments of the present disclosure. FIG. 9B is a plan view illustrating in detail a second region R2 of FIG. 9A. FIG. 9C is a cross-sectional view taken along a line E-E′ of FIG. 9A.

In FIGS. 9A to 9C, a semiconductor chip for the semiconductor package 1000A may be any one of the semiconductor chips shown in FIGS. 1A to 8C. Hereinafter, for the convenience of explanation, it is assumed that the semiconductor package 1000A includes the semiconductor chip of FIGS. 2A and 2B.

Referring to FIGS. 9A to 9C, the semiconductor package 1000A according to the present disclosure may include a substrate 1210, a first chip stack CS1, a second chip stack CS2, a connection substrate 1220, and a mold layer MD.

The substrate 1210 may be a printed circuit substrate (PCB) that includes a substrate pad 1211 provided on an upper surface thereof. The substrate pad 1211 may include a conductive material, e.g., copper. The substrate 1210 may have a structure in which an insulating pattern and a wiring pattern are alternately stacked. According to some example embodiments, external connection terminals, such as a solder ball, a solder bump, or a solder pad, may be arranged on a lower surface of the substrate 1210.

The first chip stack CS1 may be disposed on the substrate 1210. The first chip stack CS1 may include semiconductor chips CH1, CH2, CH3, and CH4 stacked in the third direction (Z direction) on the substrate 1210.

The semiconductor chips CH1, CH2, CH3, and CH4 may be a memory chip. As an example, each of the semiconductor chips CH1, CH2, CH3, and CH4 may include a dynamic random access memory (DRAM), however, this is merely an example. According to some example embodiments, each of the semiconductor chips CH1, CH2, CH3, and CH4 may include an SRAM, a flash memory, or the like. The semiconductor package 1000A may include n semiconductor chips, and n is four in FIGS. 9A to 9C. However, the number of the semiconductor chips should not be limited to four.

A first adhesive layer BL1 may be disposed on a lower surface of a first semiconductor chip CH1 among the semiconductor chips CH1, CH2, CH3, and CH4. The first adhesive layer BL1 may be disposed between the first semiconductor chip CH1 and the substrate 1210 and may have a first thickness T1. Similarly, second, third, and fourth adhesive layers BL2, BL3, and BL4 may be respectively disposed on lower surfaces of second, third, and fourth semiconductor chips CH2, CH3, and CH4 among the semiconductor chips CH1, CH2, CH3, and CH4. The second, third, and fourth adhesive layers BL2, BL3, and BL4 may have a second thickness T2.

In some example embodiments, the first thickness T1 of the first adhesive layer BL1 may be greater than the second thickness T2 of the second, third, and fourth adhesive layers BL2, BL3, and BL4 to ensure that the first chip stack CS1 is more stably positioned on the substrate 1210. Each of the first, second, third, and fourth adhesive layers BL1, BL2, BL3, and BL4 may have a die attach film (DAF).

A first protective layer PL1 may be disposed on an upper surface of the first semiconductor chip CH1 among the semiconductor chips CH1, CH2, CH3, and CH4. Similarly, second, third, and fourth protective layers PL2, PL3, and PL4 may be disposed on upper surfaces of the second, third, and fourth semiconductor chips CH2, CH3, and CH4, respectively.

Each of the semiconductor chips CH1, CH2, CH3, and CH4 may include a top pad 1130 and a side pad 1120B electrically connected to the top pad 1130. Each side pad 1120B may be exposed to the outside through a sidewall.

The semiconductor chips CH1, CH2, CH3, and CH4 may be arranged in an offset stack structure. As an example, the semiconductor chips CH1, CH2, CH3, and CH4 may be stacked while each being shifted in the first direction, forming a step shape heading upward in the first direction. For example, each of the semiconductor chips CH1, CH2, CH3, and CH4 may protrude from another semiconductor chip placed thereunder to the first direction (X direction). Since the semiconductor chips CH1, CH2, CH3, and CH4 are stacked in the step shape, a portion of the upper surface and the top pad 1130 of the semiconductor chips CH1, CH2, CH3, and CH4 may be exposed to the outside.

The semiconductor chips CH1, CH2, CH3, and CH4 may be connected to each other through a printed pattern. The semiconductor chips CH1, CH2, CH3, and CH4 may be electrically connected to the substrate pad 1211 on the substrate 1210 through the printed pattern.

As an example, the side pad 1120B of the first semiconductor chip CH1 may be connected to the substrate pad 1211 through a first printed pattern PP1a. The side pad 1120B of the second semiconductor chip CH2 may be connected to the top pad 1130 of the first semiconductor chip CH1 through a second printed pattern PP2a. Similarly, the side pad 1120B of the third semiconductor chip CH3 may be connected to the top pad 1130 of the second semiconductor chip CH2 through a third printed pattern PP3a, and the side pad 1120B of the fourth semiconductor chip CH4 may be connected to the top pad 1130 of the third semiconductor chip CH3 through a fourth printed pattern PP4a.

In some example embodiments, the printed pattern may be a conductive pattern formed through an inkjet print process. As an example, an ink used in the inkjet print process may be a solution in which conductive particles, such as Au, Ag, or Cu particles, are dispersed in a solvent. When the ink is discharged onto a target area where the conductive pattern is to be formed and the solvent evaporates, only the conductive particles may remain in the target area, and thus, the conductive pattern may be formed.

Side surface insulating layers SIL1a, SIL2a, SIL3a, and SIL4a may be formed on sidewall portions of corresponding semiconductor chips, respectively, to provide the target areas for each printed pattern to be formed. In some example embodiments, each side surface insulating layer may be formed in a triangular shape to allow each printed pattern to have a plate shape without bending.

As an example, a first side surface insulating layer SIL1a may be formed to cover a portion of the sidewall of the first semiconductor chip CH1 and a portion of the upper surface of the substrate 1210, and the first side surface insulating layer SIL1a may have the triangular shape. The first printed pattern PP1a may be formed along an inclined surface of the first side surface insulating layer SIL1a to have the plate shape without bending. As an example, the second side surface insulating layer SIL2a may be formed to cover a portion of the sidewall of the second semiconductor chip CH2 and a portion of an upper surface of the first semiconductor chip CH1, and the second side surface insulating layer SIL2a may have the triangular shape. The second printed pattern PP2a may be formed along an inclined surface of the second side surface insulating layer SIL2a to have the plate shape without bending. Similarly, each of the third side surface insulating layer SIL3a and the fourth side surface insulating layer SIL4a may be formed in the triangular shape, and thus, each of the third printed pattern PP3a and the fourth printed pattern PP4a may be formed to have the plate shape.

Due to low viscosity properties of the ink used in the inkjet print process, a phenomenon in which a portion of the printed pattern formed at an edge of the semiconductor chip is disconnected or a portion of the printed pattern with significant curvature is disconnected may occur. This phenomenon may be referred to as an open risk. In some example embodiments, electrical connections between the semiconductor chips and/or between the semiconductor chip and the substrate pad may be broken, leading to the occurrence of a defective semiconductor package. On the other hand, since the printed patterns PP1a, PP1b, PP1c, and PP1d according to the present disclosure have the plate shape, the open risk may be limited and/or prevented from occurring. Thus, the operational reliability may be improved.

The second chip stack CS2 may be disposed on the substrate 1210, and the second chip stack CS2 may be spaced apart from the first chip stack CS1 in the horizontal direction. Semiconductor chips of the second chip stack CS2 may be stacked in a similar manner to the semiconductor chips of the first chip stack CS1, and thus, details thereof will be omitted.

The connection substrate 1220 may be disposed on the first chip stack CS1 and the second chip stack CS2. The connection substrate 1220 may have a width greater than a sum of a width of an uppermost semiconductor chip among the semiconductor chips of the first chip stack CS1 and a width of an uppermost semiconductor chip among the semiconductor chips of the second chip stack CS2. The connection substrate 1220 may overlap the uppermost semiconductor chip among the first chip stack CS1 and the uppermost semiconductor chip among the second chip stack CS2 when viewed in the plane. As an example, the connection substrate 1220 may include a bare silicon, an organic substrate, or an organic film.

The mold layer MD may be disposed on the substrate 1210. The mold layer MD may cover the first chip stack CS1, the second chip stack CS2, and the connection substrate 1220. As an example, the mold layer MD may include an insulating polymer material such as an epoxy molding compound (EMC).

As described with reference to FIGS. 9A to 9C, the semiconductor package 1000A according to the present disclosure may include the semiconductor chips including the top pad and the side pad, and the semiconductor chips may be electrically connected to each other through the printed pattern. In some example embodiments, the printed pattern may be formed to have the plate shape. Accordingly, the open risk phenomenon may be limited and/or prevented from occurring in the semiconductor package 1000A, and the operational reliability of the semiconductor package 1000A may be improved. The semiconductor chips of the semiconductor package 1000A may be electrically connected to each other by a printed pattern method instead of a bonding wire method. Thus, the semiconductor package 1000A implemented by the printed pattern method may be made thinner compared to the semiconductor package implemented by the bonding wire method, and storage capacity per unit volume may increase.

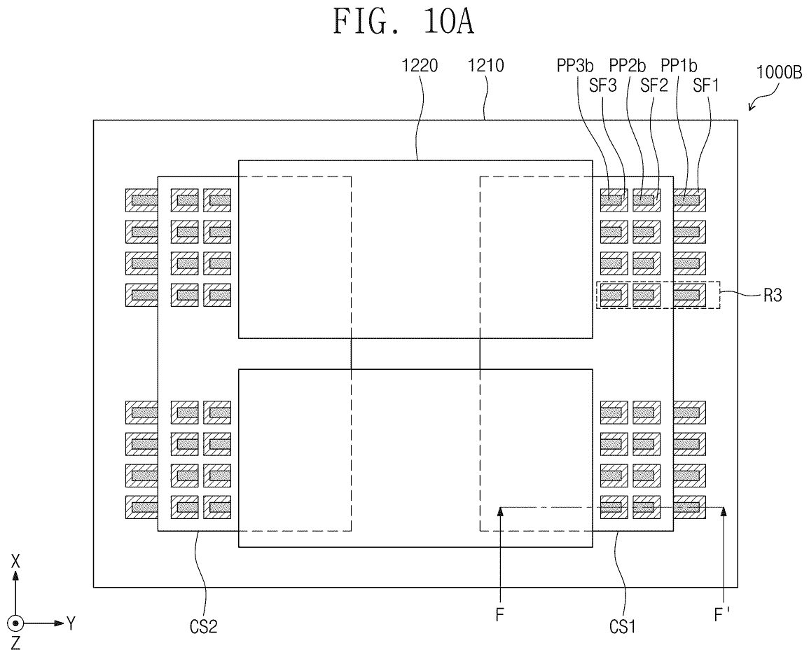

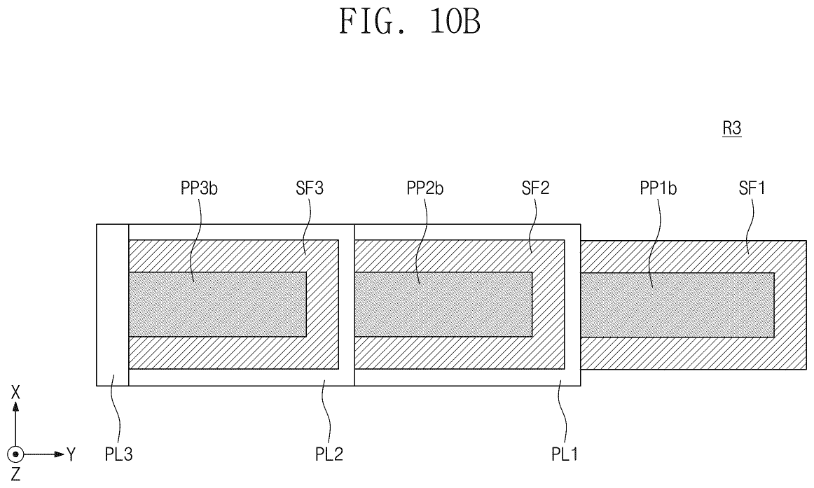

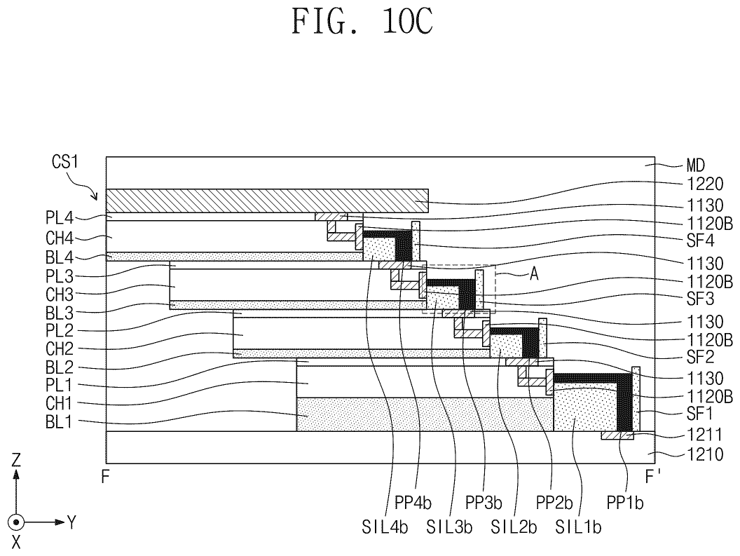

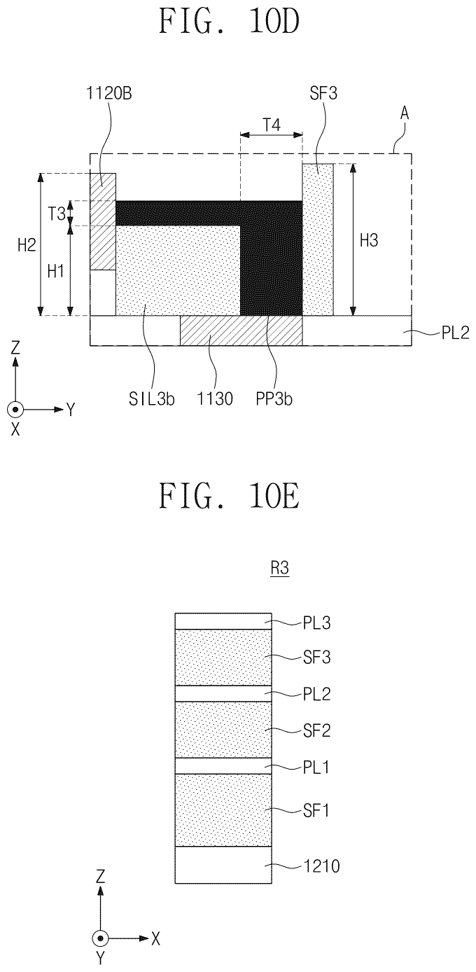

FIG. 10A is a plan view illustrating a semiconductor package 1000B according to some example embodiments of the present disclosure. FIG. 10B is a plan view illustrating in detail a third region R3 of FIG. 10A. FIG. 10C is a cross-sectional view taken along a line F-F′ of FIG. 10A. FIG. 10D is a cross-sectional view illustrating in detail a region A of FIG. 10C. FIG. 10E is a side view illustrating in detail a region R3 of FIG. 10A.

In FIGS. 10A to 10E, a semiconductor chip for the semiconductor package 1000B may be any one of the semiconductor chips shown in FIGS. 1A to 8C. Hereinafter, for the convenience of explanation, it is assumed that the semiconductor package 1000B includes the semiconductor chip of FIGS. 2A and 2B. The semiconductor package 1000B is similar to the semiconductor package 1000A described with reference to FIGS. 9A to 9C. Accordingly, the same or similar elements will be assigned with the same or similar reference numerals, and detailed descriptions of the same or similar elements will be omitted.

Referring to FIGS. 10A to 10C, the semiconductor package 1000B according to the present disclosure may include a substrate 1210, a first chip stack CS1, a second chip stack CS2, a connection substrate 1220, and a mold layer MD.

The substrate 1210 may be a printed circuit substrate (PCB) that includes a substrate pad 1211 provided on an upper surface thereof.

The first chip stack CS1 and the second chip stack CS2 may be disposed on the substrate 1210.

The first chip stack CS1 may include semiconductor chips CH1, CH2, CH3, and CH4 arranged in an offset stack structure on the substrate 1210. Each of the semiconductor chips CH1, CH2, CH3, and CH4 may include a top pad 1130 and a side pad 1120B electrically connected to the top pad 1130. Each side pad 1120B may be exposed to the outside through a sidewall. The second chip stack CS2 may be arranged similar to the first chip stack CS1.

The semiconductor chips CH1, CH2, CH3, and CH4 may be connected to each other through a printed pattern. The semiconductor chips CH1, CH2, CH3, and CH4 may be electrically connected to the substrate pad 1211 on the substrate 1210 through the printed pattern.

In some example embodiments, side surface insulating layers SIL1a, SIL2a, SIL3a, and SIL4a may be formed on sidewall portions of corresponding semiconductor chips, respectively, to provide a target area for each printed pattern to be formed. As an example, the side surface insulating layers SIL1a, SIL2a, SIL3a, and SIL4a may be formed in a quadrangular shape.

Support structures SF1, SF2, SF3, and SF4 may be formed at a certain distance away from corresponding side surface insulating layers, respectively, to provide the target area for each printed pattern to be formed.

As an example, a first support structure SF1 may be formed at a certain distance from a first side surface insulating layer SIL1b in the second direction (Y direction). A second support structure SF2 may be formed at a certain distance from a second side surface insulating layer SIL2b in the second direction (Y direction). Similarly, a third support structure SF3 may be formed at a certain distance from a third side surface insulating layer SIL3b in the second direction (Y direction), and a fourth support structure SF4 may be formed at a certain distance from the fourth side surface insulating layer SIL4b in the second direction (Y direction).

Then, an ink used in an inkjet print process may be sprayed onto the side surface insulating layer. In some example embodiments, a space between the side surface insulating layer and the support structure spaced apart from the side surface insulating layer by the certain distance may be filled with the ink. Then, when a solvent of the ink evaporates, the printed pattern that electrically connects the semiconductor chips to each other or electrically connects the semiconductor chip and the substrate pad may be formed.

As an example, a first printed pattern PP1b may be formed on an upper surface of the first side surface insulating layer SIL1b and in a space between the first side surface insulating layer SIL1b and the first support structure SF1. The first printed pattern PP1b may connect the side pad 1120B of the first semiconductor chip CH1 and the substrate pad 1211. A second printed pattern PP2b may be formed on an upper surface of the second side surface insulating layer SIL2b and in a space between the second side surface insulating layer SIL2b and the second support structure SF2. The second printed pattern PP2b may connect the side pad 1120B of the second semiconductor chip CH2 and the top pad 1130 of the first semiconductor chip CH1. Similarly, a third printed pattern PP3b may be formed on an upper surface of the third side surface insulating layer SIL3b and in a space between the third side surface insulating layer SIL3b and the third support structure SF3 and may connect the side pad 1120B of the third semiconductor chip CH3 and the top pad 1130 of the second semiconductor chip CH2. A fourth printed pattern PP4b may be formed on an upper surface of the fourth side surface insulating layer SIL4b and in a space between the fourth side surface insulating layer SIL4b and the fourth support structure SF4 and may connect the side pad 1120B of the fourth semiconductor chip CH4 and the top pad 1130 of the third semiconductor chip CH3.

According to some example embodiments, a height in the third direction (Z direction) of each support structure may be greater than a height of the corresponding side surface insulating layer.

As an example, referring to FIG. 10D, based on an upper surface of the second semiconductor chip CH2, the height of the third support structure SF3 may be defined as ‘H3’, and the height of the third side surface insulating layer SIL3b may be defined as ‘H1’. Since the height H3 of the third support structure SF3 is greater than the height H1 of the third side surface insulating layer SIL3b, the printed pattern PP3b may be stably formed on the third side surface insulating layer SIL3b and the top pad 1130.

According to some example embodiments, a height in the third direction (Z direction) of each support structure may be higher than the height at which the corresponding side pad is located.

As an example, referring to FIG. 10D, based on the upper surface of the second semiconductor chip CH2, a height of the third side pad 1120B may be defined as ‘H2’. Since the height H3 of the third support structure SF3 is higher (e.g., greater than) than the height H2 of the third side pad 1120B, the third side pad 1120B may not be exposed when viewed from the side surface.

According to some example embodiments, a width of a portion of each printed pattern, which is in contact with the top pad, may be larger than the width of a portion of each printed pattern, which is in contact with the side pad, to limit and/or prevent the occurrence of the open risk phenomenon.

As an example, referring to FIG. 10D, the third printed pattern PP3b may have a bending portion bent from the second direction (Y direction) to the third direction (Z direction). In some example embodiments, a width of a portion of the third printed pattern PP3b, which is in contact with the side pad 1120B of the third semiconductor chip CH3, may be defined as ‘T3’, and a width of a portion of the third printed pattern PP3b, which is in contact with the top pad 1130 of the second semiconductor chip CH2, may be defined as ‘T4’. In some example embodiments, the width T4 of the portion of the third printed pattern PP3b, which is in contact with the top pad 1130 of the second semiconductor chip CH2, may be greater than the width T3 of the portion, which is in contact with the side pad 1120B of the third semiconductor chip CH3. Therefore, although the third printed pattern PP3b includes the bending portion, the open risk may be limited and/or prevented from occurring, and the operational reliability may be improved.

As described with reference to FIGS. 10A to 10E, the semiconductor package 1000B according to the present disclosure may include the semiconductor chips each including the top pad and the side pad, and the semiconductor chips may be electrically connected to each other by the printed pattern. In some example embodiments, the printed pattern may have the bending portion, and the width of the portion that is in contact with the top pad may be greater than the width of the portion that is in contact with the side pad. Accordingly, the open risk phenomenon may be limited and/or prevented from occurring in the semiconductor package 1000B, and the operational reliability of the semiconductor package 1000B may be improved. The semiconductor chips of the semiconductor package 1000B may be electrically connected to each other by the printed pattern method instead of the bonding wire method. Thus, the semiconductor package 1000B implemented by the printed pattern method may be made thinner compared to the semiconductor package implemented by the bonding wire method, and storage capacity per unit volume may increase.

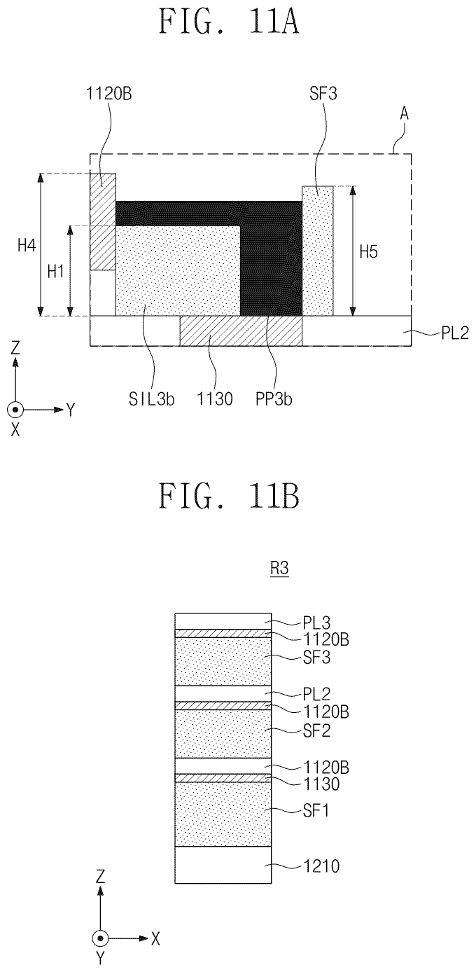

FIG. 11A is a cross-sectional view illustrating a region A of FIG. 10C according to some example embodiments of the present disclosure. FIG. 11B is a side view FIGS. 10A and 11A.

The cross-sectional view of FIG. 11A and the side view of FIG. 11B are similar to those of FIGS. 10D and 10E. Accordingly, the same or similar elements will be assigned with the same or similar reference numerals, and detailed descriptions of the same or similar elements will be omitted.

In FIGS. 10A to 10E, the height of each support structure in the third direction (Z direction) is described as being higher than the height at which the corresponding side pad is placed, however, this is merely an example, and the present disclosure should not be limited thereto or thereby. According to some example embodiments, the height of each support structure in the third direction (Z direction) may be lower than the height at which the corresponding side pad is placed.

As an example, referring to FIGS. 11A and 11B, based on an upper surface of a second semiconductor chip CH2, a height of a third side pad 1120B may be defined as ‘H4’, and a height of a third support structure SF3 may be defined as ‘H5’. Since the height H5 of the third support structure SF3 is lower (e.g., less than) than the height H4 of the third side pad 1120B, a portion of the third side pad 1120B may be exposed to the outside when viewed from the side surface.

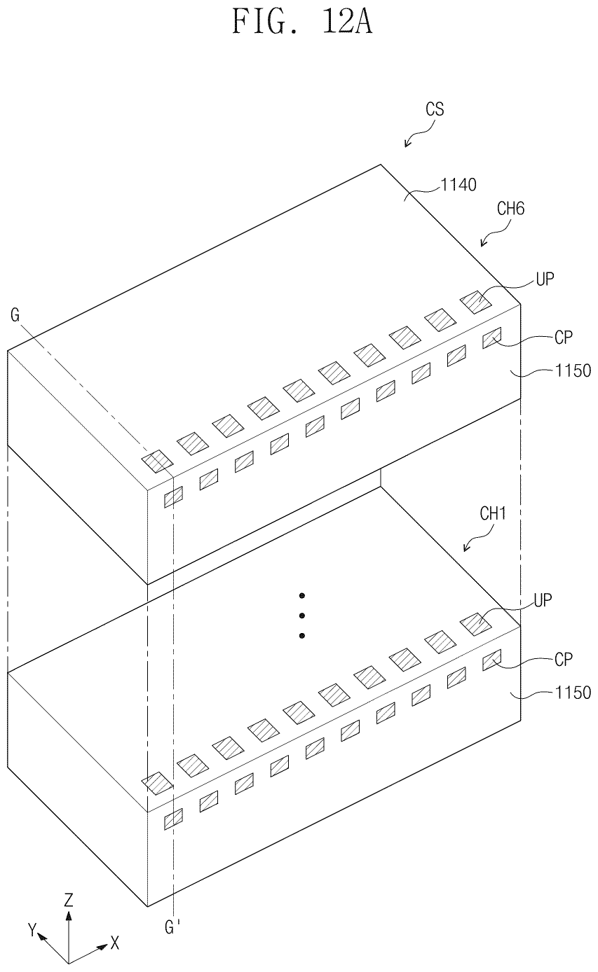

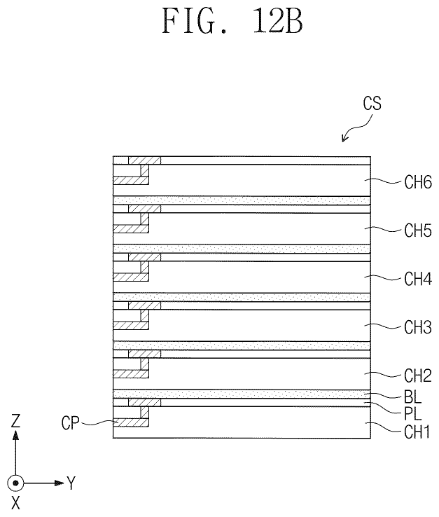

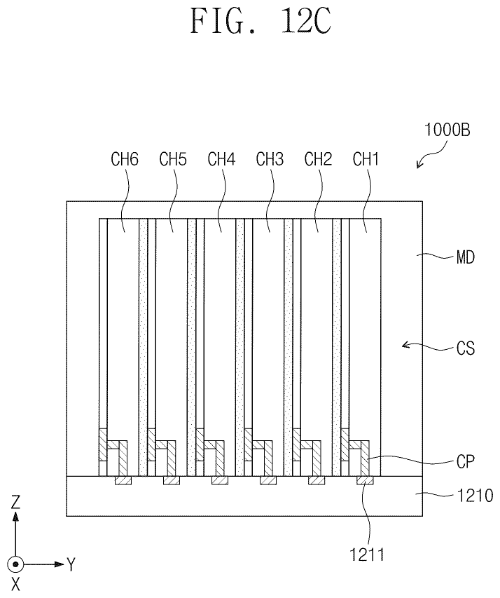

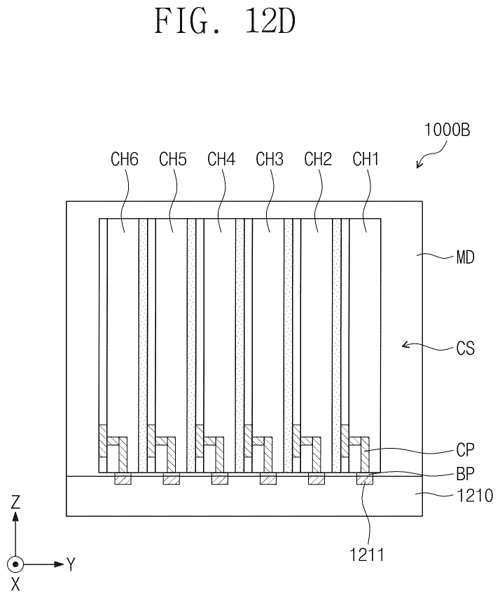

FIGS. 12A to 12D are views illustrating a semiconductor package 1000C according to some example embodiments of the present disclosure. For example, FIG. 12A is a perspective view illustrating a chip stack according to some example embodiments of the present disclosure. FIG. 12B is a cross-sectional view illustrating the chip stack according to some example embodiments of the present disclosure. FIG. 12C is a cross-sectional view illustrating the semiconductor package 1000C including the chip stack of FIG. 12B according to some example embodiments of the present disclosure. FIG. 12D is a cross-sectional view illustrating a semiconductor package 1000C including the chip stack of FIG. 12B according to some example embodiments of the present disclosure.

In FIGS. 12A to 12D, the semiconductor chip of the semiconductor package 1000C may be any one of the semiconductor chips shown in FIGS. 1A to 8C. Hereinafter, for the convenience of explanation, it is assumed that the semiconductor package 1000C includes the semiconductor chip of FIGS. 5A to 5C. The semiconductor package 1000C is similar to the semiconductor packages 1000A and 1000B described with reference to FIGS. 9A to 11C. Accordingly, the same or similar elements will be assigned with the same or similar reference numerals, and detailed descriptions of the same or similar elements will be omitted.

Referring to FIGS. 12A and 12B, a chip stack CS may be provided. The chip stack CS may include semiconductor chips CH1 to CH6 stacked in the third direction (Z direction). The chip stack CS may include n semiconductor chips, and n is six as shown in FIGS. 12A to 12D. However, the number of the semiconductor chips should not be limited to six.

An adhesive layer BL may be interposed between one semiconductor chip and another semiconductor chip. A protective layer PL may be formed on an upper surface of each of the semiconductor chips, and a top pad UP may be exposed through the protective layer PL. A conductive pattern CP may be exposed to the outside through a sidewall of each of the semiconductor chips. The conductive pattern CP may be used as a side pad.

In some example embodiments, the semiconductor chips of the chip stack CS may be aligned with each other while being stacked. For example, different from the semiconductor package 1000A described with reference to FIGS. 9A to 9C, the chip stack CS may have an aligned stack structure instead of the offset stack structure.

Referring to FIG. 12C, the chip stack CS may be mounted on a substrate 1210. The chip stack CS mounted on the substrate 1210 may be covered by a mold layer MD. In some example embodiments, the chip stack CS may be mounted to allow at least one of the conductive patterns CP exposed to the outside to be connected to a substrate pad 1211 of the substrate 1210. As an example, the chip stack CS may be mounted on the substrate 1210 after rotating about 90 degrees, and thus, the conductive patterns CP used as an input/output pad may be directly connected to the substrate pad 1211 of the substrate 1210.

In some example embodiments, since the conductive patterns CP used as the input/output pad are connected to the substrate pad 1211, a physical distance between the semiconductor chips CH1 to CH6 and an external logic circuit connected through the substrate 1210 may be shortened. Accordingly, the communication speed may be improved.

Since the chip stack CS has the aligned stack structure rather than the offset stack structure, a memory capacity of the semiconductor package 1000C may increase. For example, waste of space resulting from the offset stack structure may decrease, and the memory capacity provided per unit volume may increase.

Referring to FIG. 12D, bumps BP may be formed between the conductive patterns CP of the chip stack CS and the substrate pads 1211 of the substrate 1210. As an example, the bumps may be formed in the conductive patterns CP of the chip stack CS. Then, the chip stack CS may be mounted on the substrate 1210 after rotating about 90 degrees, and thus, the conductive patterns CP used as the input/output pad may be connected to the substrate pad 1211 of the substrate 1210 through the bump BP.

In FIGS. 1A to 12C, each of the semiconductor chips is described as including the top pad UP, however, this is merely an example, and the present disclosure should not be limited thereto or thereby. According to some example embodiments, the semiconductor chips may be implemented to include only the conductive pattern CP used as the side pad.

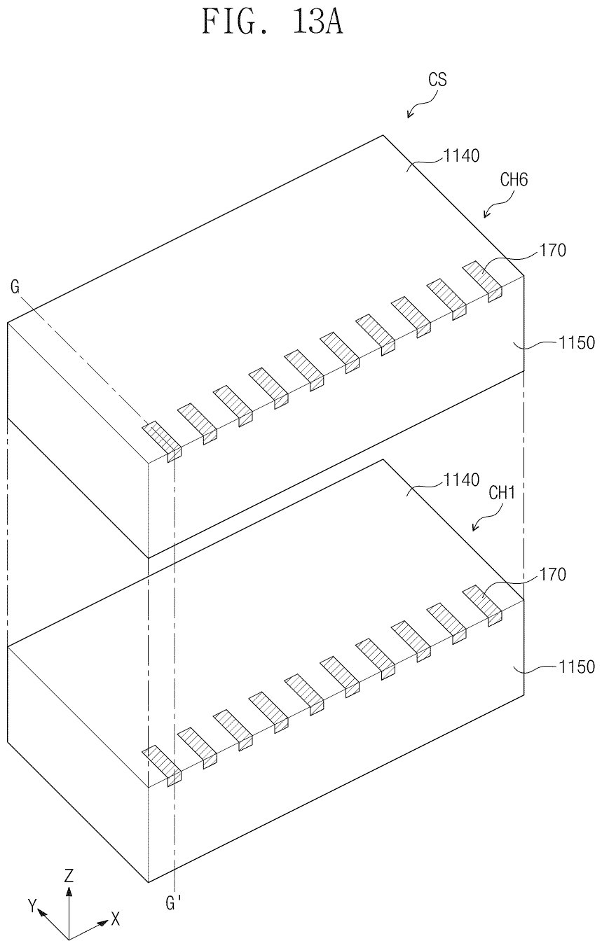

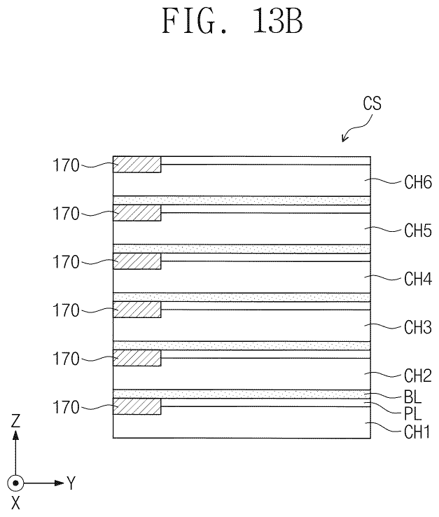

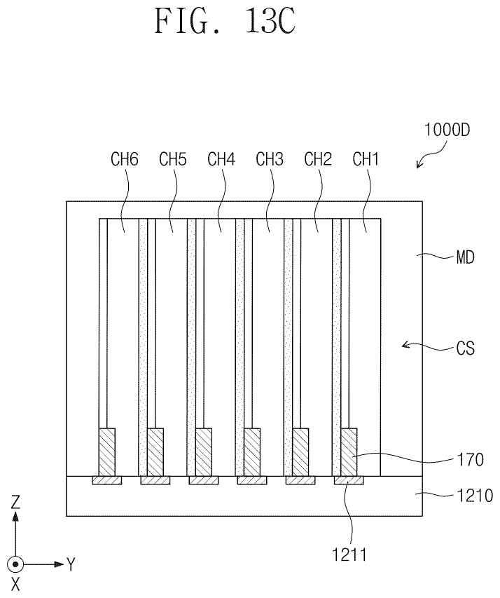

FIGS. 13A to 13C are views illustrating a semiconductor package 1000D according to some example embodiments of the present disclosure. For example, FIG. 13A is a perspective view illustrating a chip stack according to some example embodiments of the present disclosure. FIG. 13B is a cross-sectional view illustrating a chip stack according to some example embodiments of the present disclosure. FIG. 13C is a cross-sectional view illustrating the semiconductor package 1000D including the chip stack of FIG. 13B.

In FIGS. 13A to 13C, the semiconductor chip of the semiconductor package 1000D may be any one of the semiconductor chips of FIGS. 1A to 8C. Hereinafter, for the convenience of explanation, it is assumed that the semiconductor package 1000D includes the semiconductor chip of FIGS. 4A and 4B. The semiconductor package 1000D is similar to the semiconductor packages 1000A, 1000B, and 1000C described with reference to FIGS. 9A to 12C. Accordingly, the same or similar elements will be assigned with the same or similar reference numerals, and detailed descriptions of the same or similar elements will be omitted.

Referring to FIGS. 13A and 13B, a chip stack CS may be provided. The chip stack CS may include semiconductor chips CH1 to CH6 stacked in the third direction (Z direction).

An adhesive layer BL may be interposed between one semiconductor chip and another semiconductor chip. A protective layer PL may be formed on an upper surface of each semiconductor chip, and a conductive pattern 170 of each semiconductor chip may be exposed to the outside without being covered by the protective layer PL. The conductive pattern 170 may be exposed to the outside through a sidewall of each semiconductor chip. The conductive pattern 170 may be used as a side pad. In some example embodiments, the semiconductor chips of the chip stack CS may be aligned with each other while being stacked.

Referring to FIG. 13C, the chip stack CS may be mounted on a substrate 1210. The chip stack CS mounted on the substrate 1210 may be covered by a mold layer MD. In some example embodiments, the chip stack CS may be mounted to allow at least one of the conductive patterns 170 exposed to the outside to be connected to a substrate pad 1211 of the substrate 1210. As an example, the chip stack CS may be mounted on the substrate 1210 after rotating about 90 degrees, and thus, the conductive patterns 170 used as an input/output pad may be directly connected to the substrate pad 1211 of the substrate 1210.

In some example embodiments, since the conductive patterns 170 used as the input/output pad are connected to the substrate pad 1211, a physical distance between the semiconductor chips CH1 to CH6 and an external logic circuit connected through the substrate 1210 may be shortened. Accordingly, the communication speed may be improved.

Since the chip stack CS has the aligned stack structure rather than the offset stack structure, a memory capacity of the semiconductor package 1000D may increase. That is, waste of space resulting from the offset stack structure may decrease, and the memory capacity provided per unit volume may increase.

Some example embodiments of the inventive concepts further provide a method of manufacturing a semiconductor package that includes forming a first semiconductor chip including a first top pad exposed through an upper surface of the first semiconductor chip, and a first side pad electrically connected to the first top pad, the first side pad being exposed through a sidewall of the first semiconductor chip; forming a second semiconductor chip including a second top pad exposed through an upper surface of the second semiconductor chip, and a second side pad electrically connected to the second top pad, the second side pad being exposed through a sidewall of the second semiconductor chip; stacking the second semiconductor chip on the first semiconductor chip; and printing a conductive pattern between the first top pad and the second side pad that electrically connects the first semiconductor chip and the second semiconductor chip.

In some example embodiments, the method of manufacturing a semiconductor package further includes forming a side surface insulating layer on the upper surface of the first semiconductor chip, the side surface insulating layer covering at least a portion of the second side pad and at least a portion of the first top pad.

In some example embodiments of the method of manufacturing a semiconductor package, the side surface insulating layer is formed as having a triangular shape and an inclined surface, and the conductive pattern is printed as having a plate shape along the inclined surface of the side surface insulating layer.

In some example embodiments, the method of manufacturing a semiconductor package further includes forming a support structure on the upper surface of the first semiconductor chip, the support structure being spaced apart from the side surface insulating layer along a horizontal direction.

In some example embodiments of the method of manufacturing a semiconductor package, the side surface insulating layer is formed as having a quadrangular shape, and the conductive pattern is formed on an upper surface of the side surface insulating layer and between a side surface of the side surface insulating layer and a side surface of the support structure.

In some example embodiments of the method of manufacturing a semiconductor package, a first portion of the conductive pattern between the side surface of the side surface insulating layer and the side surface of the support structure is formed as having a first width greater than a second width of the conductive pattern on the upper surface of the side surface insulating layer.

In some example embodiments of the method of manufacturing a semiconductor package, the support structure is formed as having a first height from the upper surface of the first semiconductor chip that is greater than a second height of the second side pad from the upper surface of the first semiconductor chip.

In some example embodiments of the method of manufacturing a semiconductor package, the support structure is formed as having a first height from the upper surface of the first semiconductor chip that is less than a second height of the second side pad from the upper surface of the first semiconductor chip.

In some example embodiments of the method of manufacturing a semiconductor package, the forming the first semiconductor chip includes forming a first chip including a peripheral circuit; forming a second chip including at least one memory block; and stacking the second chip on the first chip after being inverted. The forming the second chip includes forming a common source line having a plate shape and extending in a first direction and a second direction; forming an upper insulating layer covering the common source line; forming an input/output contact plug extending in a third direction perpendicular to the common source line, the input/output contact plug being electrically connected to an input/output pad; and forming an upper metal contact connected to the input/output contact plug. The first top pad is on the upper insulating layer.

In some example embodiments of the method of manufacturing a semiconductor package, the first side pad is in the first chip and bonded to the upper metal contact.

In some example embodiments of the method of manufacturing a semiconductor package, the forming the first semiconductor chip further includes forming a first conductive pattern connecting the first top pad and the first side pad, and the forming the second semiconductor chip further includes forming a second conductive pattern connecting the second top pad and the second side pad.

In some example embodiments of the method of manufacturing a semiconductor package, the first top pad and the first side pad are formed in a single first metal layer, and the second top pad and the second side pad are formed in a single second metal layer.

While the present disclosure has been described with reference to some example embodiments thereof, it will be apparent to those of ordinary skill in the art that various changes and modifications may be made thereto without departing from the spirit and scope of the present disclosure as set forth in the following claims.

What is claimed is:

1. A semiconductor package comprising:
a first semiconductor chip;
a second semiconductor chip stacked on the first semiconductor chip; and
a printed pattern electrically connecting the first semiconductor chip and the second semiconductor chip,
the first semiconductor chip comprising
a first top pad exposed through an upper surface of the first semiconductor chip, and
a first side pad electrically connected to the first top pad, the first side pad being exposed through a sidewall of the first semiconductor chip,
the second semiconductor chip comprising
a second top pad exposed through an upper surface of the second semiconductor chip, and
a second side pad electrically connected to the second top pad, the second side pad being exposed through a sidewall of the second semiconductor chip,
wherein the printed pattern electrically connects the first top pad and the second side pad.

2. The semiconductor package of claim 1, further comprising a side surface insulating layer on the upper surface of the first semiconductor chip, the side surface insulating layer covering at least a portion of the second side pad and at least a portion of the first top pad.

3. The semiconductor package of claim 2, wherein the side surface insulating layer has a triangular shape and has an inclined surface, and the printed pattern has a plate shape along the inclined surface of the side surface insulating layer.

4. The semiconductor package of claim 2, further comprising a support structure on the upper surface of the first semiconductor chip, the support structure being spaced apart from the side surface insulating layer along a horizontal direction.

5. The semiconductor package of claim 4, wherein the side surface insulating layer has a quadrangular shape, and
the printed pattern is on an upper surface of the side surface insulating layer, and between a side surface of the side surface insulating layer and a side surface of the support structure.

6. The semiconductor package of claim 5, wherein a first portion of the printed pattern between the side surface of the side surface insulating layer and the side surface of the support structure has a first width greater than a second width of the printed pattern on the upper surface of the side surface insulating layer.

7. The semiconductor package of claim 5, wherein the support structure has a first height from the upper surface of the first semiconductor chip that is greater than a second height of the second side pad from the upper surface of the first semiconductor chip.

8. The semiconductor package of claim 5, wherein the support structure has a first height from the upper surface of the first semiconductor chip that is less than a second height of the second side pad from the upper surface of the first semiconductor chip.

9. The semiconductor package of claim 1, wherein the first semiconductor chip comprises
a first chip including a peripheral circuit; and
a second chip comprising at least one memory block, the second chip being stacked on the first chip after being inverted,
wherein the second chip comprises
a common source line having a plate shape and extending in a first direction and a second direction,
an upper insulating layer covering the common source line,
an input/output contact plug extending in a third direction perpendicular to the common source line, the input/output contact plug being electrically connected to an input/output pad, and
an upper metal contact being connected to the input/output contact plug, and
the first top pad is on the upper insulating layer.

10. The semiconductor package of claim 9, wherein the first side pad is in the first chip and bonded to the upper metal contact.

11. The semiconductor package of claim 1, wherein the first semiconductor chip further comprises a first conductive pattern connecting the first top pad and the first side pad, and
the second semiconductor chip further comprises a second conductive pattern connecting the second top pad and the second side pad.

12. The semiconductor package of claim 1, wherein the first top pad and the first side pad are in a single first metal layer, and the second top pad and the second side pad are in a single second metal layer.

13. A semiconductor package comprising:
a substrate comprising a plurality of substrate pads, the substrate extending in a first direction; and
a plurality of semiconductor chips extending in a second direction perpendicular to the first direction, the plurality of semiconductor chips being on the substrate next to each other along the first direction,
wherein each semiconductor chip from among of the plurality of semiconductor chips comprises
a top pad exposed through an upper surface of the semiconductor chip, and
a pad conductive pattern exposed through a sidewall of the semiconductor chip, the pad conductive pattern being electrically connected to the top pad,
wherein the pad conductive pattern of at least one semiconductor chip from among the plurality of semiconductor chips is electrically connected to at least one substrate pad from among the plurality of substrate pads.

14. The semiconductor package of claim 13, wherein the plurality of semiconductor chips are stacked in an aligned stack structure and are mounted on the substrate with sidewalls of the plurality of semiconductor chips facing the substrate.

15. The semiconductor package of claim 13, wherein the at least one of semiconductor chip comprises:
a first chip including a peripheral circuit; and
a second chip comprising memory blocks, the second chip being stacked on the first chip after being inverted,
wherein the second chip comprises
a common source line having a plate shape and extending in the first direction and the second direction,
an upper insulating layer covering the common source line,
an input/output contact plug extending in a third direction perpendicular to the common source line, the input/output contact plug being electrically connected to an input/output pad, and
an upper metal contact being connected to the input/output contact plug, and
the top pad is on the upper insulating layer.

16. The semiconductor package of claim 15, wherein the pad conductive pattern is in the first chip and is bonded to the upper metal contact.

17. A semiconductor chip comprising:
an upper surface;
a sidewall;
a top pad exposed through the upper surface; and
a side pad electrically connected to the top pad, the side pad being exposed through the sidewall.

18. The semiconductor chip of claim 17, further comprising:
a first chip including a peripheral circuit; and
a second chip comprising memory blocks, the second chip being stacked on the first chip after being inverted,
wherein the second chip comprises
a common source line having a plate shape and extending in a first direction and a second direction,
an upper insulating layer covering the common source line,
an input/output contact plug extending in a third direction perpendicular to the common source line, the input/output contact plug being electrically connected to an input/output pad, and
an upper metal contact being connected to the input/output contact plug, and
the top pad is on the upper insulating layer.

19. The semiconductor chip of claim 18, wherein the side pad is in the first chip and is bonded to the upper metal contact.

20. The semiconductor chip of claim 17, further comprising a conductive pattern connecting the top pad and the side pad.
